(19) United States
(12) Patent Application Publication
(10) Pub. No.: US 2010/0084713 A1
(43) Pub. Date: Apr. 8, 2010

(54) Semiconductor device manufacturing method and semiconductor device

(75) Inventors: Takashi Nakagawa, Tokyo (JP); Toru Tatsumi, Tokyo (JP); Kenzo Manabe, Tokyo (JP); Kensuke Takahashi, Tokyo (JP); Makiko Oshida, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC CORPORATION, TOKYO (JP)

(21) Appl. No.: 12/311,428

(22) PCT Filed: Sep. 27, 2007
(86) PCT No.: PCT/JP2007/068890

§ 371 Date: Mar. 30, 2009

(30) Foreign Application Priority Data
Sep. 29, 2006 (JP) 2006-268017

(51) Int. Cl. H01L 27/092; H01L 21/8238

(52) U.S. Cl. 257/369; 438/199; 257/E27.062; 257/E21.632

(57) ABSTRACT

A second mask is provided so as to cover a second gate pattern and a first gate pattern is heated to a temperature at which a material gas containing a first metal thermally decomposes, polysilicon constituting the first gate pattern is reacted with the first metal for silicidation under the conditions that the layer of the first metal does not deposit, and thus the first gate pattern is turned into a first gate electrode constituted by a silicide of the first metal. After the second mask is removed, a first mask is provided so as to cover the first electrode and the second gate pattern is heated to a temperature at which the material gas thermally decomposes, polysilicon constituting the second gate pattern is reacted with the first metal for silicidation under the conditions that the layer of the first metal does not deposit, and thus the second gate pattern is turned into a second gate electrode constituted by the silicide of the first metal. Then, the first mask is removed. With such a manufacturing method, a silicide layer is formed without adding an annealing process.

### TECHNICAL FIELD

The present invention relates to a technique of a semiconductor device and a manufacturing method of the same and, more particularly, to a semiconductor device in which a silicide layer constituting a gate electrode is formed in a special process, and a manufacturing method of the same.

### BACKGROUND ART

In the development of the most-sophisticated CMOS (complementary MOS) device for which miniaturization of transistor advances, in order to improve the characteristics of transistor, it is necessary to reduce the sheet resistance of a diffusion layer and a gate electrode constituting a source region and a drain region. Because of this, for the purpose of reducing the sheet resistance, the salicide technique is used, in which after depositing, a gate electrode material is coated with a metal and subjected to annealing processing, and thus only the metal coated on the gate electrode material is silicidated and then unreacted metal is removed by selective etching.

Recently, there is a problem of deterioration of a drive current due to the depletion of gate electrode made of polysilicon (poly-Si) and a technique to avoid the depletion of gate electrode by applying a metal gate electrode is discussed. As a material used for the metal gate electrode, a pure metal, or a metal compound, such as metal nitride, silicide material, or germanium compound, is discussed, however, in each case, it must be possible to set the threshold voltage (Vth) of N-type MOSFET and P-type MOSFET to an appropriate value.

Consequently, a technique is required, which forms a silicide layer having optimum resistance value and work function for the source/drain region, the gate electrode of N-type MOSFET, and the gate electrode of P-type MOSFET. Further, as the element structure becomes finer and more complex, a method of forming a silicide layer excellent in evenness in a large area and coatability is required.

Conventionally, the method of forming the silicide layer has been discussed. In Non-patent Literature 1, after a Ni layer is formed on a polysilicon gate pattern by the sputtering method, the Ni layer is reacted with polysilicon by carrying out annealing processing and thus a silicide layer is formed. In this case, according to the description, it is possible to control the composition of the silicide by the annealing temperature and to form Ni₂Si by the annealing processing in a range of 300° C. to 350° C., NiSi by the annealing processing in a range of 350° C. to 650° C., and NiSi₂ by the annealing processing in a range of 650° C. or more. This formation method has characteristics in that a metal film is deposited in a region in which the silicide layer is formed and then a silicide composition having desired characteristics can be formed by adjusting the annealing temperature.

In Non-patent Literature 2, a MOSFET is disclosed, in which a HfSiON high dielectric constant film is used as a gate insulating film and a Ni silicide electrode completely silicidated as a gate electrode is used. In this MOSFET, by controlling the composition of the Ni silicide at the time of the formation of the Ni silicide crystal phase constituting the gate electrode, the effective work function is controlled. For example, by using a Ni₃Si gate electrode for the P-type MOSFET and a NiSi₂ gate electrode for the N-type MOSFET, it is made possible to set Vth of a CMOS transistor constituted by these MOSFETs to ±0.3 V. Further, as in Non-patent Literature 1, the composition of the Ni silicide is controlled by the temperature etc., in the annealing process after depositing Ni on the gate electrode by the sputtering method.

In Non-patent Literature 3, as a gate insulating film, SiO₂ is used and nickel is deposited by the sputtering method on a poly-Si (polysilicon) structure the gate length of which has been processed to 70 nm to 150 nm and having a film thickness of 100 nm, and after that, a nickel silicide is formed by carrying out various kinds of annealing processing. Then, after that, using a transmission electron microscope (TEM), transmission electron diffraction (TED), and X-ray diffraction (XRD), the evaluation of the dependence of the composition of nickel silicide on the annealing temperature and the gate length is made. Non-patent Literature 3 describes that the composition of nickel silicide changes depending on the annealing temperature and the gate length, as a result. For example, it is described that by the annealing processing at 700° C., in a structure with a long gate length, a silicide layer having the NiSi, Ni₂Si, Ni₅Si₂ crystal phases is formed and in a fine structure with a gate length of 70 nm, a silicide layer having the Ni₃Si crystal phase is formed.

In Non-patent Literature 2 and Non-patent Literature 3, there is a description of the formation of NiSi₂, CoSi₂, FeSi₂ directly on a silicon substrate by supplying Ni, Co, Fe at a low rate (low supply rate) onto the silicon substrate using MBE or the vapor deposition method. The use of the formation methods described in these Literatures has an advantage that a silicide layer having a Si-rich composition can be formed at a temperature lower than that of the method described in Non-patent Literature 1.

In Patent Literature 1, there is disclosed a method of forming a titanium silicide (TiSi₂) layer having a C54 structure by coating titanium on a silicon substrate using high-frequency plasma by the chemical vapor deposition method (CVD). This technique is characterized by having an advantage that the annealing process can be reduced because the silicide layer can be formed directly, as in Non-patent Literature 2.

Patent Literature 2 and Patent Literature 3 disclose a method of forming a titanium silicide (TiSi₂) layer having a C54 structure by introducing a titanium tetrachloride gas and a hydrogen gas onto a silicon substrate and using the CVD method using plasma excitation with the electron cyclotron resonance, helicon wave, and ECR. This technique is characterized by having an advantage that the annealing process can be reduced because the silicide layer can be formed directly, as in Patent Literature 1.

Patent Literature 4 discloses a method of forming a titanium silicide layer on a silicon substrate by the plasma CVD method using (1) titanium tetrachloride and hydrogen gases or (2) titanium tetrachloride, silane-based, and hydrogen gases.

Patent Literature 5 discloses a method of forming a titanium silicide (TiSi₂) film on a silicon substrate by the CVD method using titanium tetrachloride and silane gases as a material gas and by adding hydrogen fluoride to the material gas.

Patent Literature 6, Patent Literature 7, and Non-patent Literature 3 disclose a method of forming a nickel silicide film on a silicon substrate by the CVD method using a material containing Ni and a material containing Si.

Non-patent Literature 4 describes the formation of a nickel silicide film by the CVD method using Ni(PF₃)₄ as a material gas containing Ni and Si₃H₈ as a material gas containing Si and the possibility that the composition of the nickel silicide film can be changed by the amount of supply of Si₃H₈ at the time of the formation.

Patent Literature 8 discloses the description of the deposition of Pt by the CVD method using Pt(PF₃)₄ as a metal material gas and describes that a Pt film is formed by supplying the Pt(PF₃)₄ material onto a silicon substrate heated to a temperature of 300° C. or less and the deposition rate of Pt increases at a temperature of 300° C. or more, however, a platinum silicide is formed simultaneously.

Non-patent Literature 1: J. Vac. Sci. Technol. B19(6), November/December 2001 L2026

Non-patent Literature 2: International electron devices meeting technical digest 2004, p 91

Non-patent Literature 3: 2006 MRS spring meeting ABSTRACT, p 113

Non-patent Literature 4: Appl. Phys. Lett., Vol. 74, No 21, 24 May 1999 p. 3137

Non-patent Literature 5: Mater. Res. Soc. Symp. Proc. 3 20, 1994 p 221

Non-patent Literature 6: Extended Abstracts of International Conference on Solid State Devices and Materials 2005, p 508

Patent Literature 1: Unexamined Japanese Patent Application KOKAI Publication No. H10-144625

Patent Literature 2: Unexamined Japanese Patent Application KOKAI Publication No. H8-97249

Patent Literature 3: Unexamined Japanese Patent Application KOKAI Publication No. H7-297136

Patent Literature 4: Unexamined Japanese Patent Application KOKAI Publication No. 2000-58484

Patent Literature 5: Unexamined Japanese Patent Application KOKAI Publication No. H8-283944

Patent Literature 6: Unexamined Japanese Patent Application KOKAI Publication No. 2003-328130

Patent Literature 7: Unexamined Japanese Patent Application KOKAI Publication No. 2005-93732

Patent Literature 8: U.S. Pat. No. 5,459,099 Specification

### DISCLOSURE OF INVENTION

### Problem to be Solved by the Invention

The silicide layer formation techniques described above, however, have the following problems.

Firstly, the technique to form the Ni film by the sputtering method and then control the Ni/Si composition ratio of the nickel silicide by the annealing conditions, as described in Non-patent Literature 1, requires the annealing process, causing a problem that the manufacturing cost is increased. Further, there may be a case where plasma damage to the element occurs and the element characteristics are lost because the metal film formation for forming the silicide is carried out by the sputtering method.

In addition, when NiSi₂ is used as a gate electrode material, for example, the annealing process at 650° C. or more is required, and therefore, there may be a case where the resistance of the silicide layer provided on the source/drain region increases at the time of annealing and the diffusion of Ni contained in the gate electrode into the gate insulating film causes the element characteristics to deteriorate. Further, there may be a case where the formation of the silicide layer in a three-dimensional structure and in a trench structure with a high aspect ratio becomes difficult from the standpoints of the coatability, spreading ability, embeddability, etc., of the film.

The gate electrode in Non-patent Literature 1 has a mixed phase of NiSi₂ and NiSi and when such a gate electrode having a mixed phase is used in the configuration of the semiconductor device in Non-patent Literature 1, the variations in the element characteristics may be caused. Further, Non-patent Literature 1 describes that the annealing temperature for obtaining the NiSi crystal phase changes depending on the kind/concentration of the impurities of the substrate when forming the silicide at a low temperature of 400° C. or less. Consequently, the silicide layer formation method according to this Literature has a problem that the number of processes increases because the annealing temperature needs to be optimized in accordance with the kind/concentration of the impurities of the substrate.

Secondly, as described in Non-patent Literature 3, the silicidation of the gate electrode by the sputtering method described in Non-patent Literature 1 and Non-patent Literature 2 has different amounts of consumption of Ni depending on the gate pattern. Consequently, there is a problem that the formation rate and the composition/crystal phase of the silicide layer change depending on the gate length even if the annealing processing is carried out at a high temperature of 700° C. Consequently, the composition control technique of the silicide layer using the sputtering method is not suitable for the precision control of the silicide composition.

Thirdly, with the method of forming the silicide layer having a Si-rich composition by using the MBE method, the vapor deposition method, etc., and supplying metal at a low rate as described in Non-patent Literature 4 and Non-patent Literature 5, it is difficult to form an even silicide layer in a large area. In addition, the formation of the silicide layer in a three-dimensional structure and in a trench structure with a high aspect ratio becomes difficult from the standpoints of the coatability, spreading ability, embeddability, etc., of the film. Further, in these Literatures there is not at all any description of the method of changing the silicide composition in a wide range and the methods are not suitable for the formation of a silicide layer having an optimum composition for the N-type MOSFET gate electrode and the P-type MOSFET gate electrode.

Fourthly, with the silicide layer formation methods using the plasma CVD described in Patent Literature 1, Patent Literature 2, Patent Literature 3, and Patent Literature 4, there may be a case where the element characteristics deteriorate due to the plasma damage to the element at the time of the silicide layer formation. Further, with the gas phase formation method by plasma excitation, there may be a case where unwanted elements decompose due to the plasma excitation and are adsorbed to the substrate surface, and they work as impurities on the substrate surface, and therefore, impeding the silicide layer formation.

Consequently, there is a case where the formation of the silicide layer (TiSi₂) having a Si-rich composition is possible, however, the formation of the silicide layer having a metal-rich composition is difficult. Further, there is a problem that the chloride radical generated by the plasma excitation is reacted with Si on the substrate and thereby the substrate is etched. According to Patent Literature 3, the flow rate of TiCl₄ is controlled to suppress the influence of the chloride radical, however, the formation of a completely flat silicide layer without the substrate being etched cannot be achieved. Further, according to the silicide layer formation method using TiCl₄ and the silane-based gas in the same Literature, the above-described influence of etching can be suppressed, however, the silicide layer is formed on, for example, the insulating film, such as the gate sidewall, other than the source/drain region and the gate electrode, and therefore, it becomes difficult to selectively remove the silicide layer on the gate sidewall in the subsequent etching process.

Fifthly, according to the silicide film formation by the CVD method using the material gas containing the metal and the material gas containing Si described in Patent Literature 5, Patent Literature 6, Patent Literature 7, and Non-patent Literature 4, the silicide layer is formed also on, for example, the insulating film, such as the gate sidewall, other than the source/drain region and the gate electrode. Consequently, it is difficult to selectively remove the silicide layer on the gate sidewall in the subsequent etching process.

Sixthly, according to the silicide film formation method described in Patent Literature 8, the metal film and the silicide layer are formed on the silicon substrate at the same time, and therefore, it is difficult to control the composition of the silicide layer. In this case, in order to control the composition of the silicide layer, it is necessary to adjust the temperature after the metal film is formed and then to carry out the annealing processing as in Non-patent Literature 1, and therefore, it is impossible to expect the reduction in the number of processes. In addition, the method described in Patent Literature 8 has not sufficiently discussed the structure of the composition/crystal phase of the silicide layer to be formed, the control method of the composition/crystal phase, and the effect of the reduction in the silicidation temperature. Because of this, this method proves not to be suitable for forming the silicide layer having an optimum composition corresponding to the N-type MOSFET gate electrode and the P-type MOSFET gate electrode, respectively.

Seventhly, with the semiconductor device that uses the N-type MOSFET gate electrode of NiSi₂ described in Non-patent Literature 2, NiSi₂ is exposed onto the surface in its manufacturing process. This NiSi₂ is soluble in the HF aqueous solution, and therefore, there arises a problem that NiSi₂ elutes during the wet etching processing using the HF aqueous solution in the subsequent process.

As described above, the conventional manufacturing methods are not suitable for forming the silicide layer having an optimum composition corresponding to the N-type MOSFET gate electrode and the P-type MOSFET gate electrode, respectively. That is, at the time of the manufacture of the semiconductor device comprising the N-type MOSFET and the P-type MOSFET, there may be a case where at least the four processes (the deposition process of the N-type MOSFET gate electrode material/annealing process for the gate electrode formation, the deposition process of the N-type MOSFET gate electrode material/annealing process for the gate electrode formation) are required to form the gate electrodes of both MOSFETs. Consequently, the cost is increased and at the same time, the thermal load applied to the members (the source/drain region, gate electrode materials, etc.) constituting the semiconductor device at the time of the formation of the gate electrode increases, leading to the deterioration of the device characteristics of the semiconductor device. Further, with the conventional manufacturing methods, it is difficult to control the gate electrode of the N-type MOSFET and the P-type MOSFET to the desired even silicide composition. Furthermore, when the metal layer is deposited by the sputtering method etc., there may be a case where plasma damage to the element occurs and the element characteristics deteriorate.

An object of the present invention is to directly form a gate electrode constituted by a silicide layer at the time of the supply of a material gas without adding a process, such as annealing, when manufacturing an N-type MOSFET gate electrode and a P-type MOSFET gate electrode. Another object of the present invention is to provide a manufacturing method of a semiconductor device, the method capable of controlling with high precision the composition/crystal phase of a silicide layer when forming a gate electrode. Still another object of the present invention is to provide a semiconductor device having the resistant property against an HF aqueous solution in a subsequent process, such as etching, and the element characteristics of which do not deteriorate without involving a considerable increase in the number of additional processes.

### Means for Solving the Problem

A manufacturing method of a semiconductor manufacturing apparatus according to the present invention is a manufacturing method of a semiconductor device comprising N-type MOSFET and P-type MOSFET of planar type, having:

a process for preparing a silicon substrate in which an N-type region and a P-type region are insulated and isolated via an element insulation region;

a first formation process for forming a gate insulating film and a first gate pattern constituted by polysilicon in the form of a projection on the P-type region, and forming a gate insulating film and a second gate pattern constituted by polysilicon in the form of a projection on the N-type region;

a second formation process for forming source/drain regions on both sides of the first gate pattern in the P-type region and on both sides of the second gate pattern in the N-type region, respectively;

a process for depositing an interlayer insulating film on the entire surface; a process for removing the interlayer insulating film to expose the first and second gate patterns;

a process for providing a second mask so as to cover the region on the gate insulating film provided on the N-type region;

a first silicidation process for supplying a material gas containing a first metal that can be used to form a silicide with polysilicon constituting the first gate pattern, heating the first gate pattern to a temperature at which the material gas thermally decomposes, causing the first metal and the polysilicon constituting the first gate pattern to react with each other under the conditions that the layer of the first metal does not deposit on the first gate pattern, and thus turning the first gate pattern into a first gate electrode constituted by a silicide (A) of the first metal; a process for removing the layer of the first metal that has deposited on parts other than the second mask and the first gate electrode;

a process for providing a first mask so as to cover the region on the gate insulating film provided on the P-type region;

a second silicidation process for supplying a material gas containing the first metal that can be used to form a silicide with polysilicon constituting the second gate pattern, heating the second gate pattern to a temperature at which the material gas thermally decomposes, causing the first metal and the polysilicon constituting the second gate pattern to react with each other under the conditions that the layer of the first metal does not deposit on the second gate pattern, and thus turning the second gate pattern into a second gate electrode constituted by a silicide (B) of the first metal; and

a process for removing the layer of the first metal that has deposited on parts other than the first mask and the second gate electrode.

In the first formation process, it is possible to:

form a silicon oxide film or a silicon oxynitride film as the gate insulating film;

form polysilicon containing at least one kind of impurity element selected from a group consisting of N, P, As, Sb, and Bi as the first gate pattern; and

form polysilicon containing at least one kind of impurity element selected from a group consisting of B, Al, Ga, In, and Tl as the second gate pattern.

It is possible to carry out the first and second silicidation processes so that the silicide (A) and the silicide (B) are silicides having different composition ratios of the first metal and silicon from each other.

It is also possible to configure the method so that at least one process of the first and second silicidation processes has a first silicide layer formation process for forming a first silicide layer and a second silicide layer formation process for forming a second silicide layer with a first metal content higher than that of the first silicide layer on the first silicide layer by supplying a material gas under the conditions that the amount of supply of the material gas is larger than that in the first silicide layer formation process.

It is also possible to configure the method so that at least one process of the first and second silicidation processes has a first silicide layer formation process for forming a first silicide layer and a second silicide layer formation process for forming a second silicide layer with a first metal content higher than that of the first silicide layer on the first silicide layer by reducing the temperature at which the material gas thermally decomposes lower than that in the first silicide layer formation process.

It is also possible to configure the method so that at least one process of the first and second silicidation processes has a first silicide layer formation process for forming a first silicide layer and a second silicide layer formation process for forming a second silicide layer with a first metal content higher than that of the first silicide layer on the first silicide layer by reducing the atmospheric pressure when the first metal is reacted with polysilicon lower than that in the first silicide layer formation process.

Preferably, the amount of supply of material gas in the second silicidation process is larger than the amount of supply of material gas in the first silicidation process.

Preferably, the heating temperature of the polysilicon constituting the second gate pattern in the second silicidation process is lower than the heating temperature of the polysilicon constituting the first gate pattern in the first silicidation process.

Preferably, the atmospheric pressure when the first metal is reacted with the polysilicon in the second silicidation process is lower than the atmospheric pressure when the first metal is reacted with the polysilicon in the first silicidation process.

The first metal is, for example, at least one kind of metal selected from a group consisting of Ni, Pt, Co, W, and Ru.

It is possible to configure the method so that C is not contained in the material gas in the first and second silicidation processes.

Further, the method is configured so that, in the first and second silicidation processes, the material gas contains at least one kind of gas selected from a group consisting of Ni(PF₃)₄, Ni(BF₂)₄, Pt(PF₃)₄, Pt(BF₂)₄, Co(PF₃)₆, Co(BF₂)₆, W(PF₃)₆, W(BF₂)₆, Ru(PF₃)₅, and Ru(BF₂)₅.

In at least one process of the first and second silicidation processes, preferably, the material gas is Ni(PF₃)₄ or Ni(BF₂)₄ and the NiSi₂ crystal phase is formed as at least one silicide of the silicide (A) and the silicide (B).

Further, in at least one process of the first and second silicidation processes, as the conditions that the layer of the first metal does not deposit on the gate pattern, at least one gate pattern of the first and second gate patterns can be heated to 150° C. to 600° C. as the temperature at which the material gas thermally decomposes.

Further, in at least one process of the first and second silicidation processes, as the conditions that the layer of the first metal does not deposit on the gate pattern, the atmospheric pressure when the polysilicon constituting at least one gate pattern of the first and second gate patterns is reacted with the first metal can be set to 1×10⁻⁴ Torr to 100 Torr.

In at least one process of the first and second silicidation processes, preferably, the material gas is Ni(PF₃)₄ or Ni(BF₂)₄ and the NiSi crystal phase is formed as at least one silicide of the silicide (A) and the silicide (B).

Further, in at least one process of the first and second silicidation processes, as the conditions that the layer of the first metal does not deposit on the gate pattern, at least one gate pattern of the first and second gate patterns can be heated to 250° C. to 600° C. as the temperature at which the material gas thermally decomposes.

Furthermore, in at least one process of the first and second silicidation processes, as the conditions that the layer of the first metal does not deposit on the gate pattern, the atmospheric pressure when the polysilicon constituting at least one gate pattern of the first and second gate patterns is reacted with the first metal can be set to 1×10⁻⁴ Torr to 80 Torr.

In addition, in at least one process of the first and second silicidation processes, preferably, the material gas is Ni(PF₃)₄ or Ni(BF₂)₄ and the Ni₃Si crystal phase is formed as at least one silicide of the silicide (A) and the silicide (B).

Further, in at least one process of the first and second silicidation processes, as the conditions that the layer of the first metal does not deposit on the gate pattern, preferably, at least one gate pattern of the first and second gate patterns is heated to 250° C. to 500° C. as the temperature at which the material gas thermally decomposes.

Furthermore, in at least one process of the first and second silicidation processes, as the conditions that the layer of the first metal does not deposit on the gate pattern, it is possible to configure the method so that the atmospheric pressure when the polysilicon constituting at least one gate pattern of the first and second gate patterns is reacted with the first metal is 1×10⁻⁴ Torr to 10 Torr.

In addition, it is possible to configure the method so that in at least one process of the first and second silicidation processes, the material gas is Ni(PF₃)₄ or Ni(BF₂)₄ and the process has a first silicide layer formation process for forming a first silicide layer including the NiSi₂ crystal phase, and a second silicide layer formation process for forming a second silicide layer including at least one crystal phase of the NiSi crystal phase and the Ni₃Si crystal phase on the first silicide layer.

It is also possible to configure the method so that in the first silicidation process, the material gas is Ni(PF₃)₄ or Ni(BF₂)₄ and the NiSi₂ crystal phase is formed as the silicide (A) and in the second silicidation process, the material gas is Ni(PF₃)₄ or Ni(BF₂)₄ and the Ni₃Si crystal phase is formed as the silicide (B).

It is possible to configure the method so that in the first silicidation process, the material gas is Ni(PF₃)₄ or Ni(BF₂)₄ and the process has the first silicide layer formation process for forming the first silicide layer constituted by the NiSi₂ crystal phase as the silicide (A), and the second silicide layer formation process for forming the second silicide layer constituted by the NiSi crystal phase as the silicide (A) on the first silicide layer, and in the second silicide formation process, the material gas is Ni(PF₃)₄ or Ni(BF₂)₄ and the Ni₃Si crystal phase is formed as the silicide (B).

A configuration is made so as to comprise an N-type MOSFET having a P-type region provided in the silicon substrate, a gate insulating film provided on the P-type region, and a first gate electrode in the form of a projection provided on the gate insulating film, having the first silicide layer constituted by the NiSi₂ crystal phase and the second silicide layer constituted by the Ni₃Si crystal phase in the order from the gate insulating film side, and a P-type MOSFET having an N-type region provided in the silicon substrate so as to be insulated and isolated from the P-type region, a gate insulating film provided on the N-type region, and a second gate electrode constituted by the Ni₃Si crystal phase in the form of a projection provided on the gate insulating film.

The configuration can be achieved by the manufacture using the manufacturing method of a semiconductor device according to any of the above.

### EFFECTS OF THE INVENTION

With the semiconductor device and the manufacturing method of a semiconductor device according to the present invention, it is made possible to form each MOSFET gate electrode as a silicide layer in the process in one stage without requiring the deposition process of a metal film or the annealing processing process. Consequently, a considerable number of processes can be reduced through the formation processes of both gate electrodes. In addition, the temperature at which the silicide layer constituting the gate electrode is formed can be reduced, and therefore, it is possible to prevent an excessive thermal load from being imposed on the constituent parts of the semiconductor device such as silicide layer on the source/drain region and the other gate pattern or the gate electrode while one gate electrode is being formed.

With the semiconductor device and the manufacturing method of a semiconductor device according to the present invention, it is possible to form the gate electrode of the silicide layer having a desired even composition without the composition/crystal phase and the formation rate of the silicide layer constituting the gate electrode being affected by the kind/concentration of the impurities in the polysilicon gate pattern and the gate length. In addition, it is possible to form a gate electrode of an even silicide layer without involving the damage to the element in the material decomposition process and the damage to the substrate resulting from the material gas. As a result, it is possible to easily control Vth of the N-type MOSFET and the P-type MOSFET to a desired value.

Changing of the conditions at the time of silicidation is easy and it is possible to control the composition of a gate electrode to a desired composition in the direction of its thickness (direction of the normal of the silicon substrate). As a result, it is made possible to successively form a laminated structure including a silicide layer having a Si-rich composition at the lower side and a silicide layer having a metal-rich composition at the upper side as a gate electrode. In this laminated structure, the silicide layer having the Si-rich composition at the upper side is not exposed, and therefore, it is possible to prevent the silicide layer having the Si-rich composition from eluting during the wet etching process using the HF aqueous solution.

### BRIEF DESCRIPTION OF DRAWINGS

FIG. 1 is a diagram showing an example of a manufacturing apparatus of a semiconductor device of the present invention.

FIG. 2 is a diagram showing a formation mechanism of a silicide layer in the present invention and the prior art.

FIG. 3 is a diagram showing a decomposition process of a material gas in the present invention and the prior art.

FIG. 4 is a diagram showing a silicidation mechanism in the present invention and the prior art.

FIG. 5 is a diagram representing a relationship between the formation conditions of a silicide layer and the composition of a silicide layer of the present invention.

FIG. 6 is a diagram representing a relationship between the formation conditions of a silicide layer and the composition of a silicide layer of the present invention.

FIG. 7 is a diagram representing a relationship between the formation conditions of a silicide layer and the composition of a silicide layer of the present invention.

FIG. 8 is a diagram representing an example of a silicide composition when the silicidation of the present invention is carried out in two stages.

FIG. 9 is a diagram representing an example of a silicide composition when the silicidation of the present invention is carried out in two stages.

FIG. 10 is a diagram representing an example of a silicide composition when the silicidation of the present invention is carried out in two stages.

FIG. 11 is a diagram showing an example of a manufacturing method of a semiconductor device of the present invention.

FIG. 12 is a diagram showing an example of a manufacturing method of a semiconductor device of the present invention.

FIG. 13 is a diagram showing an example of a manufacturing method of a semiconductor device of the present invention.

FIG. 14 is a diagram showing an example of a manufacturing method of a semiconductor device of the present invention.

FIG. 15 is a diagram showing an example of a manufacturing method of a semiconductor device of the present invention.

FIG. 16 is a diagram showing an example of a manufacturing method of a semiconductor device of the present invention.

FIG. 17 is a diagram showing an example of a manufacturing method of a semiconductor device of the present invention.

FIG. 18 is a diagram showing an example of a manufacturing method of a semiconductor device of the present invention.

FIG. 19 is a diagram showing an example of a manufacturing method of a semiconductor device of the present invention.

FIG. 20 is a diagram showing an example of a manufacturing method of a semiconductor device of the present invention.

FIG. 21 is a diagram showing an example of a manufacturing method of a semiconductor device of the present invention.

FIG. 22 is a diagram showing an example of a manufacturing method of a semiconductor device of the present invention.

FIG. 23 is a diagram representing a relationship between the gate length and the silicide film thickness in the present invention and the prior art.

FIG. 24 is a diagram representing a relationship between the amount of dose of impurity and the silicide film thickness in the present invention and the prior art.

FIG. 25 is a diagram showing an example of a manufacturing method of a semiconductor device of the present invention.

FIG. 26 is a diagram showing an example of a manufacturing method of a semiconductor device of the present invention.

FIG. 27 is a diagram showing an example of a manufacturing method of a semiconductor device of the present invention.

FIG. 28 is a diagram showing an example of a manufacturing method of a semiconductor device of the present invention.

FIG. 29 is a diagram showing a cross-sectional structure of a silicide layer by SEM in reference example 2 and the result of the evaluation of the composition by XPS.

### DESCRIPTION OF REFERENCE SYMBOLS

101 material gas source
102 mass flow controller
103 valve
104 carrier gas source
105 mass flow controller
106 valve
107 temperature controller
108 gas introduction inlet
109 temperature controller
110 shower head
111 vacuum container
112 temperature controller
113 substrate
114 susceptor
115 oxidation processing gas source
116 heater
117 discharge pump
118 conductance valve
119 trap
120 discharge pump
121 controller
131 Ni atom (first metal)
132 Si substrate
133 silicide layer
134 metal layer
141 Si substrate
142 silicide layer
201 silicon substrate
202 element isolation region
203 gate insulating film
203a SiO₂ film
203b HfSiON film
204 polycrystal silicon (poly-Si)
205 silicon oxide film
206 extension region
207 gate sidewall
208 source/drain region
209 silicide layer
210 metal film
211 interlayer insulating film
212 N-type MOSFET region poly-Si
213 P-type MOSFET region poly-Si
214 diffusion preventive film
215 N-type MOSFET region silicide gate electrode
215a N-type MOSFET region first silicide layer
215b N-type MOSFET region second silicide layer
216 metal film
217 diffusion preventive film
218 P-type MOSFET region silicide gate electrode
219 metal film
220 silicon nitride film
251 N-type region
252 P-type region
301 silicon substrate
302 element isolation region
303 gate insulating film
304 Poly-Si
305 silicon oxide film
306 extension region
307 gate sidewall
308 source/drain region
309 metal film
310 silicide film
311 interlayer insulating film
312 additive element segregated at boundary surface between electrode and insulating film in N-type MOSFET region
313 N-type MOSFET region silicide gate electrode
314 additive element segregated at boundary surface between electrode and insulating film in P-type MOSFET region
315 P-type MOSFET region silicide gate electrode
316 N-type MOSFET region first silicide gate layer
317 N-type MOSFET region second silicide gate layer
318 P-type MOSFET region first silicide gate layer
319 P-type MOSFET region second silicide gate layer
320 silicon nitride film
351 N-type region
352 P-type region
401 silicon substrate
402 element isolation region
403 gate insulating film
404 polycrystal silicon (poly-Si)
405 gate sidewall
406 source/drain region
407 silicide layer
408 interlayer insulating film
409 metal film
410 extension region
411 silicide gate electrode
412 metal film
501 silicon oxide film
502 N-type MOSFET region first silicide gate layer
503 N-type MOSFET region second silicide gate layer
504 P-type MOSFET region silicide gate layer
505 metal film

### BEST MODE FOR CARRYING OUT THE INVENTION

Embodiments of the present invention are specifically explained below with reference to the accompanied drawings.

(Semiconductor Device)

The present invention relates to a manufacturing method of a semiconductor device in which both N-type MOSFET and P-type MOSFET of planar type comprise a silicide gate electrode, and a semiconductor device. Typically, these MOSFETs constitute a complementary MOSFET (CMOSFET). The semiconductor device has a gate insulating film and gate electrodes (first gate electrode, second gate electrode) projecting on the gate insulating film on an N-type region and a P-type region, respectively, of a silicon substrate. The N-type MOSFET gate electrode (first gate electrode) and the P-type MOSFET gate electrode (second gate electrode) are constituted by silicide (A) and silicide (B), respectively, of a first metal.

These first and second gate electrodes are formed by thermally decomposing a material gas under the conditions that the layer of the first metal does not deposit on the gate pattern. Consequently, it is possible to form a gate electrode of a silicide layer having an even composition without the constituent parts of MOSFET suffering from the damage due to high temperature processing, such as the annealing processing, and in the material decomposition process, such as that in the sputtering method.

The first metal may be constituted by one kind or more kinds of metal and preferably, is at least one kind of metal selected from a group consisting of Ni, Pt, Co, W, and Ru. For example, when Ni is used as the first metal, mention is made of a NiSi₂ crystal phase, a NiSi crystal phase, and a Ni₃Si crystal phase as the silicides (A) and (B).

In the first gate electrode and the second gate electrode, the compositions of the silicides (A) and (B) may be the same or different. When the compositions of the silicides (A) and (B) are different, it is possible to effectively control Vth of the N-type MOSFET and the P-type MOSFET to a desired value by the use of a silicide material having a desired work function as the silicides (A) and (B).

When the composition of the silicide (A) is made identical to that of the silicide (B), preferably, the first gate electrode and the second gate electrode contain different impurity elements from each other. By adding different kinds of impurity element into both the gate electrodes in this manner, the impurity elements are segregated on the boundary surface between the gate insulating film and the gate electrode at the time of silicidation for forming the gate electrode. Consequently, it is possible to effectively control Vth of the N-type MOSFET and the P-type MOSFET to a desired value by adding a desired concentration/kind of impurity element into the first and second gate electrodes and thus modulating the work functions of the constituent materials of the first and second gate electrodes. For example, after As is added to the first gate pattern, which will be turned into the N-type MOSFET, and B is added to the second gate pattern, which will be turned into the P-type MOSFET, the respective gate patterns are formed as the gate electrodes of the silicide layer having the NiSi₂ crystal phase. In this manner, it is possible to set Vth of the N-type MOSFET to 4.0 eV and that of the P-type MOSFET to 5.2 eV. As described above, even when the silicide composition of the first gate electrode of the N-type MOSFET region is the same as that of the second gate electrode of the P-type MOSFET, it is possible to modulate the work function of each gate electrode by segregating different impurity elements on the boundary surface between each gate electrode and the gate insulating film.

For the first gate electrode of the N-type MOSFET, preferably, the impurity element to be added into the gate electrode is at least one kind of impurity element selected from a group consisting of N, P, As, Sb, and Bi. For the second gate electrode of the P-type MOSFET, at least one kind of impurity element selected from a group consisting of B, Al, Ga, In, and TI is preferable. In addition, as the silicide composition of each gate electrode, the Ni₃Si crystal phase, the NiSi crystal phase, or the NiSi₂ crystal phase is preferable and the NiSi₂ crystal phase is much preferable in order to obtain the work function described below.

As described above, for the CMOSFET, it is preferable to realize Vth less than or equal to ±0.5 V and in this case, for the N-type MOSFET, it is preferable for the work function of the gate electrode to be less than or equal to the mid-gap of Si (4.6 eV), preferably, less than or equal to 4.4 eV. For the P-type MOSFET, it is preferable for the work function of the gate electrode to be more than or equal to the mid-gap (4.6 eV), preferably, more that or equal to 4.8 eV.

Because of this, in order to obtain such a CMOSFET of Vth, it is preferable to form the first gate electrode of the NiSi₂ crystal phase (silicide (A)) and the second gate electrode of the Ni₃Si crystal phase (silicide (B)).

The first and second gate electrodes may or may not contain one or more kinds of impurity element. When the first gate electrode contains an impurity element, as the impurity element, mention is made of at least one kind of impurity element selected from a group consisting of N, P, As, Sb, and Bi. When the second gate electrode contains an impurity element, as the impurity element, mention is made of at least one kind of impurity element selected from a group consisting of B, Al, Ga, In, and TI.

Further, each gate electrode may be constituted by two or more layers with different silicide compositions. In the present specification, when a plurality of silicide compositions exists in one gate electrode as described above, all of the plurality of compositions are defined as the silicide (A) or (B). When the gate electrode is constituted by two or more layers with different silicide compositions, it is preferable that the first metal content in the silicide become smaller toward the side of the gate insulating film in the direction of the film thickness of the gate electrode in the silicide composition.

As the gate electrode constituted by two or more layers, mention is made of the first gate electrode having the first silicide layer constituted by the NiSi₂ crystal phase (silicide (A)) and the second silicide layer constituted by the NiSi crystal phase (silicide (A)) from the side of the gate insulating film. In this case, as the second gate electrode, the second gate electrode constituted by the Ni₃Si crystal phase (silicide (B)) can be used. As described above, by constituting the uppermost layer of the first gate electrode by the NiSi crystal phase, it is possible to prevent the function as the gate electrode from deteriorating, which is caused when NiSi₂ elutes, in the wet etching process using the HF aqueous solution after the gate electrode is formed.

In the present invention, a semiconductor device is manufactured by the following processes:

(1) Process for preparing a silicon substrate in which an N-type region and a P-type region is insulated and isolated via an element isolation region;

(2) First formation process for forming a gate insulating film and a first gate pattern constituted by polysilicon in the form of a projection on the P-type region and forming a gate insulating film and a second gate pattern constituted by polysilicon in the form of a projection on the N-type region;

(3) A second formation process for forming source/drain regions on both sides of the first gate pattern in the P-type region and on both sides of the second gate pattern in the N-type region, respectively;

(4) A process for depositing an interlayer insulating film on the entire surface;

(5) A process for removing the interlayer insulating film to expose the first and second gate patterns;

(6) A process for providing a second mask so as to cover the exposed region (the exposed second gate pattern or the second gate electrode) on the gate insulating film provided on the N-type region;

(7) A first silicidation process for supplying a material gas containing a first metal that can be used to form a silicide with polysilicon constituting the first gate pattern, heating the first gate pattern to a temperature at which the material gas thermally decomposes, causing the first metal and the polysilicon constituting the first gate pattern to react with each other under the conditions that the layer of the first metal does not deposit on the first gate pattern, and thus turning the first gate pattern into a first gate electrode constituted by a silicide (A) of the first metal;

(8) A process for removing the second mask and the layer of the first metal that has deposited on parts other than the first gate electrode;

(9) A process for providing a first mask so as to cover the exposed region (the exposed first gate pattern or the first gate electrode) on the gate insulating film provided on the P-type region;

(10) A second silicidation process for supplying a material gas containing the first metal that can be used to form a silicide with polysilicon constituting the second gate pattern, heating the second gate pattern to a temperature at which the material gas thermally decomposes, causing the first metal and the polysilicon constituting the second gate pattern to react with each other under the conditions that the layer of the first metal does not deposit on the second gate pattern, and thus turning the second gate pattern into a second gate electrode constituted by a silicide (B) of the first metal; and

(11) A process for removing the first mask and the layer of the first metal that has deposited on parts other than the second gate electrode.

In the present specification, “polysilicon” is assumed to represent polysilicon containing no impurities or polysilicon containing impurities. The first silicidation process and the second silicidation process may be carried out simultaneously or separately. When the first silicidation process and the second silicidation process are carried out separately, the order is not specified in particular. For example, when the first silicidation process is carried out before the second silicidation process, in the above-described process (6), the second mask is provided on the exposed second gate pattern and in the above-described process (9), the first mask is provided on the exposed first gate electrode. On the other hand, when the second silicidation process is carried out before the first silicidation process, in the above-described process (6), the second mask is provided on the exposed second gate electrode and in the above-described process (9), the first mask is provided on the exposed first gate pattern.

Here, in the first and second silicidation processes, a material gas containing at least one kind of the first metal that can be used to form a silicide layer is supplied from the upper surface of the first and second gate patterns constituted by polysilicon formed into the form of a projection and exposed via the gate insulating film, respectively. Then, the first and second gate patterns are heated to a temperature at which the material gas thermally decomposes. At this time, the amount of supply of the material gas to be supplied onto the surface of the gate pattern is set to the amount of supply (supply rate) or less at which the deposition of the first metal begins on the first and second gate patterns by controlling the conditions of silicidation, such as the formation pressure, the temperature of the gate pattern, the flow rate of the material gas (amount of supply), etc. The present invention is based on the new discovery that it is made possible to selectively silicidate the first and second gate patterns only by the thermal decomposition reaction in this manner.

That is, in the manufacturing method of a semiconductor device of the present invention, the amount of supply of the material gas to be supplied onto the surface of the gate pattern is set so as to satisfy the following relationship by controlling the formation conditions (the amount of supply of the material gas, the temperature of the gate pattern, the formation pressure, etc.):

Amount of supply of material gas to be supplied onto gate pattern surface<adsorption rate of metal atom at which material gas thermally decomposes on exposed gate pattern and deposition of first metal begins on its surface.

As a result, all of the metal atoms adsorbed on the gate pattern of the exposed polysilicon are consumed in forming the silicide layer and the metal layer does not deposit on the exposed gate pattern. As described above, according to the present invention, the formation of the silicide layer advances in one stage, and therefore, it is possible to control the composition of the silicide layer constituting the gate electrode by controlling the formation conditions (the amount of supply of the material gas, the temperature of the gate pattern, the formation pressure, etc.) and to set the formation temperature of the silicide layer low.

The mechanism of the first and second silicidation for constituting the gate electrode is explained below in detail.

(Mechanism of First and Second Silicidation)

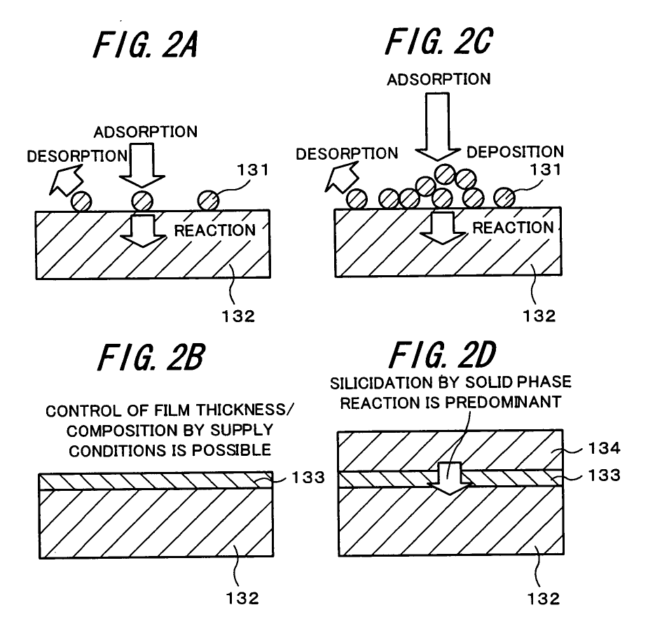

The formation mechanism of a silicide layer of the present invention is explained. FIG. 2 shows a case where a first metal is Ni 131, a material gas containing Ni 131 is supplied on a polysilicon substrate 132 of an exposed gate pattern, and a silicide layer 133 is formed. FIGS. 2A and 2B show the formation mechanism of the silicide layer 133 using the method of the present invention and FIGS. 2C and 2D show the formation mechanism of the silicide layer 133 using the conventional method.

As shown in FIG. 2A, the material gas decomposes by thermal excitation from the polysilicon substrate 132 on the surface of the gate pattern of the polysilicon substrate 132 and the Ni atom 131 is adsorbed to the surface of the gate pattern. That is, on the surface of the gate pattern, adsorption and desorption occur at all times and on the whole, a predetermined number of the Ni atoms 131 absorb to the surface of the gate pattern as an equilibrium state. Then the number of Ni atoms that are adsorbed to the surface of the gate pattern is affected by the amount of supply of the material gas, the temperature of the gate pattern, and the formation pressure (the total pressure in the reaction container in which the first and second gate patterns are installed when the first silicidation and the second silicidation are carried out: the total pressure of the material gas and the carrier gas when the material gas and the carrier gas are caused to flow through the reaction container: the atmospheric pressure at the time of silicidation), and can be controlled by these conditions.

For example, when the temperature of the gate pattern is high, the molecular motion of the Ni atom 131 becomes active and the number of the Ni atoms 131 that are desorbed from the surface of the gate pattern increases and the number of the Ni atoms that are adsorbed to the gate pattern in the equilibrium state decreases. When the formation pressure is high, the speed of the molecular motion of the Ni atom 131 is increased, and therefore, the number of the Ni atoms 131 that are desorbed from the surface of the gate pattern increases and the number of the Ni atoms that are adsorbed to the gate pattern in the equilibrium state decreases. If the amount of supply of the material gas is increased, the number of the Ni atoms to be supplied to the surface of the gate pattern increases, and therefore, it becomes more likely that a number of the Ni atoms 131 are adsorbed to the surface of the gate pattern in the equilibrium state.

Next, as shown in FIG. 2B, by the Ni atoms 131 that have been adsorbed to the region where the silicon substrate 132 on the gate pattern is exposed reacting with silicon and diffusing, the silicide layer 133 is formed. At this time, the composition/crystal structure of the silicide layer 133 are determined by the number of Ni atoms that have been adsorbed to the surface of the gate pattern in advance in the process in FIG. 2A. For example, when the number of Ni atoms is small, the NiSi₂ crystal phase having a Si-rich composition is formed. Further, as the number of Ni atoms 131 that are adsorbed increases, the silicide layer 133 having NiSi, Ni₃Si crystal phases having a Ni-rich composition is formed. Consequently, as the formation conditions of the silicide layer 133, if the temperature of the gate pattern is reduced, the amount of supply of the material gas is increased, and then the formation pressure is reduced, the silicide layer 133 having a Ni-rich composition can be formed.

Next, the conventional formation mechanism of the silicide layer 133 is shown in FIG. 2C and FIG. 2D. In the formation mechanism of the silicide layer 133 in FIG. 2C and FIG. 2D, the number of the Ni atoms 131 that have been adsorbed onto the surface on which the polysilicon substrate 132 of the gate pattern is exposed becomes larger than the number of the Ni atoms 131 to be consumed in silicidation. In addition, the Ni 131 is provided in the state where the gate pattern is set to a temperature or higher at which the material gas thermally decomposes. Consequently, in the very early stage, a predetermined number of the Ni atoms 131 are adsorbed to the surface of the gate pattern and the Ni atom 131 reacts with silicon and thereby begins to form the silicide layer 133. However, an excessive number of the Ni atoms 131 than a number of Ni atoms necessary to form the silicide layer is supplied onto the substrate 132 successively in this manner, and therefore, unreacted Ni atoms 131 occur and deposit on the silicon, and thus a metal Ni layer 134 is formed.

When the metal Ni layer 134 deposits on the polysilicon substrate 132, the Ni 131 for silicidation is not the Ni atom 131 from that which has been obtained by the thermal decomposition on the polysilicon substrate 132 but one obtained from the metal Ni layer 134 that has deposited. Because of this, in the formation of the silicide layer 133, the solid phase reaction becomes predominant. Consequently, it becomes difficult to control the film thickness/composition of the silicide layer 133 by the supply conditions (the amount of supply of material gas, the temperature of gate pattern, the formation pressure, etc.) of the Ni 131. As a result, in order to control the film thickness/composition of the silicide layer 133, it is required to carry out annealing processing in accordance with the composition/crystal phase after the metal Ni 131 has deposited as in the prior art.

From the above, in the manufacturing method of a semiconductor device of the present invention, it becomes important (1) to cause the material gas to thermally decompose by heating the gate pattern to a temperature at which the material gas thermally decomposes, and (2) to set the conditions that the amount of supply of the material gas to be supplied to the surface of the gate pattern is equal to or less than the amount of supply with which the deposition of metal begins on the exposed polysilicon region. By forming the silicide layer under these conditions, it is made possible to control the composition/crystal phase of the gate electrode constituted by the silicide layer by the conditions of the material supply. Further, it is also made possible to form the silicide layer having a Si-rich composition at low temperatures, which requires annealing processing at high temperatures in the prior art.

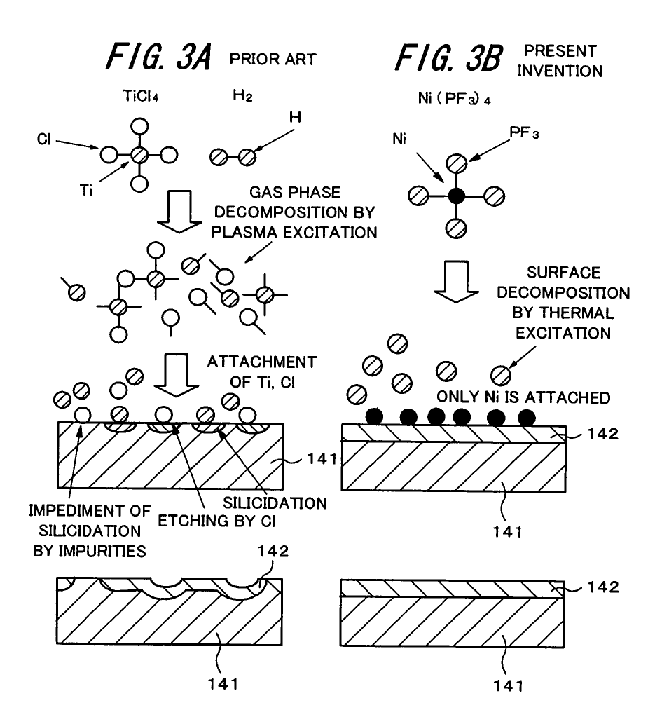

Further, as shown in FIG. 3A, when the manufacturing method according to the prior art in Patent Literature 1 and Patent Literature 2 is used, the material gas decomposes in the gas phase by plasma excitation, and therefore, not only Ti necessary for silicidation but also Cl that has decomposed in the gas phase is adsorbed to the surface of the gate pattern of a polysilicon substrate 141. The adsorbed Cl serves as an impurity on the surface of the polysilicon substrate 141 and impedes adsorption of Ti, and therefore, a problem arises that the silicidation reaction is impeded and it becomes difficult to change the composition of a silicide layer 142. In addition, Cl that has decomposed in the gas phase is supplied onto the silicon substrate 141 as chlorine radical and etches the silicon substrate 141. As described above, when the plasma CVD method is used, due to the influence of the element contained in the material gas, the impediment of silicidation and the damage to the substrate 141 exist and therefore the silicide layer 142, which is uneven as shown in FIG. 3A, is formed. In contrast to this, according to the present invention, as shown in FIG. 3B, the material gas does not decompose in the gas phase but decomposes only on the surface of the substrate 141 by thermal excitation. Consequently, only the metal in the material gas deposits on the surface of the substrate 141 and elements other than the metal are discharged. As a result, it is unlikely that elements other than the metal deposit on the surface of the substrate 141 to impede silicidation or give damage to the substrate 141.

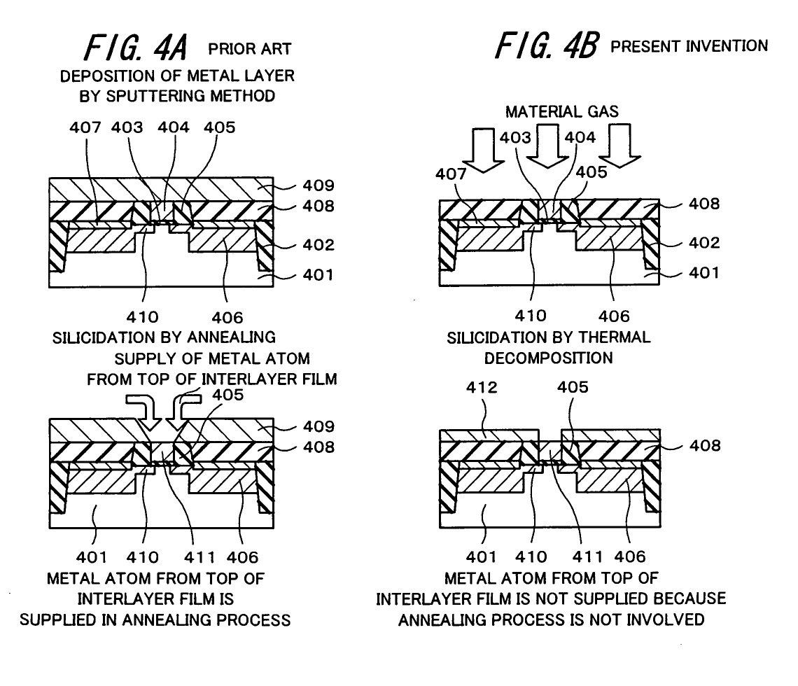

Next, a schematic diagram is shown, when a gate pattern in which polysilicon 404 is exposed as shown in FIG. 4A is turned into a silicide layer 407 using the sputtering method, which is the prior art. In FIGS. 4A, 4B, symbol numeral 401 is a silicon substrate, symbol numeral 402, an element isolation region, symbol numeral 403, a gate insulating film, symbol numeral 404, a polycrystal silicon (poly-Si), symbol numeral 405, a gate sidewall, symbol numeral 406, a source/drain region, symbol numeral 407, a silicide layer, symbol numeral 408, an interlayer insulating film, and symbol numeral 410, an extension region. First, when a metal layer 409 to form a silicide 411 is deposited, the metal film 409 is deposited on the region on which the polysilicon 404 is exposed and on the region on which it is not exposed (for example, the interlayer insulating film 408). Then, during the subsequent annealing processing, the silicide layer 411 is formed by the solid phase reaction. At this time, the metal atom that will constitute the silicide layer 411 is supplied from not only the part of the metal film 409 that has deposited on the polysilicon 404 but also the part of the metal film 409 that has deposited on the region on which the polysilicon 404 is not exposed (interlayer insulating film 408 etc.)

Consequently, as described in Non-patent Literature 3, if the length of the exposed region (for example, the gate length) becomes short, the magnitude of influence of the diffusion of metal element from the unexposed region becomes greater, and therefore, the silicide layer having a metal-rich composition is formed and it becomes difficult to control the film thickness and composition of the silicide layer.

In contrast to this, according to the manufacturing method of a semiconductor of the present invention, as shown in FIG. 4B, the silicide layer 411 is formed by only the metal atoms in the material gas supplied onto the gate pattern of the exposed polysilicon 404. Consequently, it is made possible to form the silicide layer 411 having an even composition/crystal phase without being affected by the diffusion of metal element from a metal film 412 that has deposited on the interlayer insulating film 408 etc. (irrespective of the form or size of the exposed pattern) during the period of silicidation.

(Manufacturing Method of Semiconductor Device)

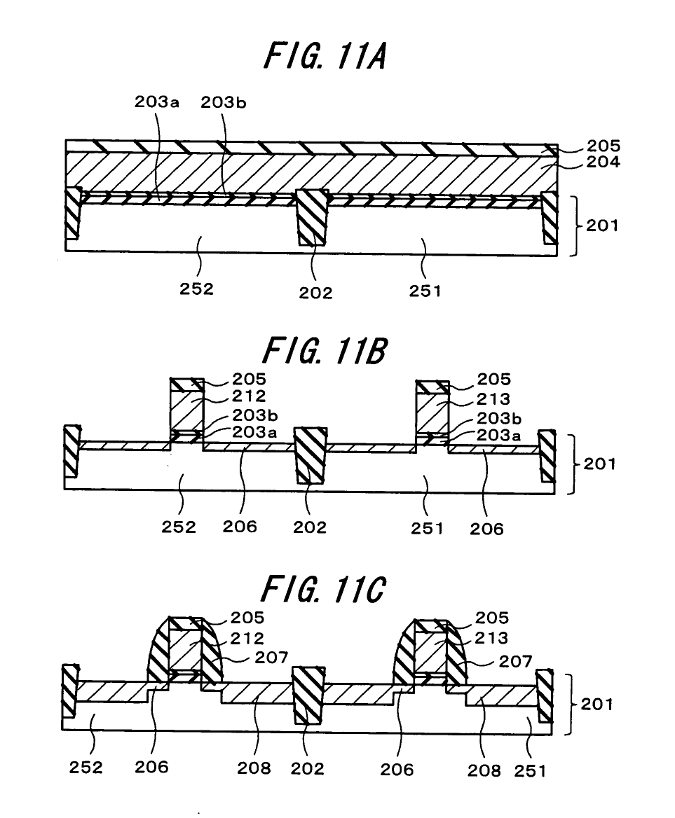

FIGS. 11 to 15 are cross-sectional views each showing an example of a manufacturing process of a semiconductor device according to the present invention. First, a silicon substrate 201 having an N-type region 251 and a P-type region 252 is prepared. Next, on the surface region of the silicon substrate 201, an element isolation region 202 is formed using the STI (Shallow Trench Isolation) technique so that the N-type region 251 and the P-type region 252 are insulated and isolated. Subsequently, on the surface of the silicon substrate 201 on which elements are isolated, a gate insulating film 203 (203a, 203b) is formed. As the gate insulating film 203, mention is made of a laminated film including a high dielectric constant insulating film, a silicon oxide film or silicon oxynitride film, and a high dielectric constant film laminated thereon.

A high dielectric constant film is made of a material having a relative dielectric constant greater than the relative dielectric constant of silicon dioxide (SiO₂) and as the material, mention is made of metal oxide, metal silicate, metal oxide into which nitrogen has been introduced, and metal silicate into which nitrogen has been introduced. As a high dielectric constant film, such one into which nitrogen has been introduced is preferable in terms of the suppression of crystallization and the improvement of the reliability of the semiconductor device. As a metal element in a high dielectric constant film, hafnium (Hf) or zirconium (Zr) is preferable, and Hf is much preferable in terms of the heat resistant property of a film and the suppression of fixed charge in a film. Further, metal oxide including Hf or Zr and Si, or metal oxynitride, which is metal oxide further including nitrogen, is preferable, HfSiO, HfSiON are much preferable, and HfSiON is most preferable.

Next, a laminated film consisting of a poly-Si film 204 and a silicon oxide film 205 is formed on the gate electrode (FIG. 11A). This laminated film is processed into the form of a gate pattern using the lithography technique and the RIE (Reactive Ion Etching) technique. In this manner, on the N-type region 251, the gate insulating films 203a, 203b in the form of a projection, a second gate pattern 213 constituted by a polysilicon layer, and the mask 205 are formed, and on the P-type region 252, the gate insulating films 203a, 203b in the form of a projection, a first gate pattern 212 constituted by a polysilicon layer, and the mask 205 are formed, respectively (first formation process).

Subsequently, a mask (not shown) is provided on the N-type region 251, ions are implanted using the mask and the mask 205 as a mask, and an extension diffusion layer region 206 is formed in a self-alignment manner in the P-type region 252. At this time, ions of impurity element may be implanted into the poly-Si film (first gate pattern) without the provision of the above-mentioned mask 205. For example, in order to realize an N-type MOSFET, it is recommended to implant ions of N, P, As, Sb, Bi, etc., which are N-type impurities, into the polysilicon.

Next, after the mask provided on the N-type region 251 is removed, a mask (not shown) is provided on the P-type region 252, ions are implanted using the mask and the mask 205 as a mask, and the extension diffusion layer region 206 is formed in a self-alignment manner in the N-type region 251 (FIG. 11B). At this time, ions of impurity element may be implanted into the poly-Si film (second gate pattern) without the provision of the above-mentioned mask 205. For example, in order to realize a P-type MOSFET, it is recommended to implant ions of B, Al, In, Ga, Tl, etc., which are P-type impurities, into the polysilicon.

Further, the silicon nitride film and the silicon oxide film are deposited sequentially and then, a gate sidewall 207 is formed on both side surfaces of the first and second gate patterns 212, 213, respectively, by carrying out etch-back. In this state, a mask (not shown) is provided again on the N-type region 251 and using the mask, the mask 205, and the gate sidewall 207 as a mask, ions of N-type impurity are implanted into the P-type region 252.

Next, after the mask provided on the N-type region is removed, a mask (not shown) is provided on the P-type region 252 and using the mask, the mask 205, and the gate sidewall 207 as a mask, ions of P-type impurity are implanted into the N-type region 251. After that, through the activation annealing, source/drain regions 208 are formed on both sides of the second gate pattern 213 in the N-type region 251 and on both sides of the first gate pattern 212 in the P-type region 252, respectively (FIG. 11C: second formation process).

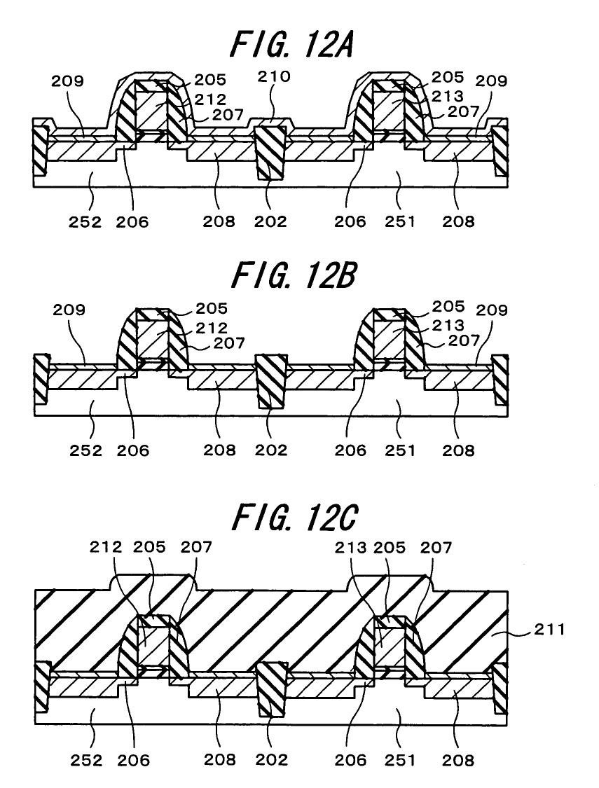

Next, as shown in FIG. 12A, a metal film 210 is deposited on the entire surface and using the gate electrode, the gate sidewall 207, and STI as a mask, a silicide layer 209 is formed only on the source/drain region 208 by the salicide technique. It is preferable to use a Co silicide, Ni silicide, or Ti silicide for the silicide layer 209 and it is most preferable to use the Ni mono-silicide that can make the contact resistance lowest. As a deposition method of the metal film 210, the sputtering method and the CVD method can be used.

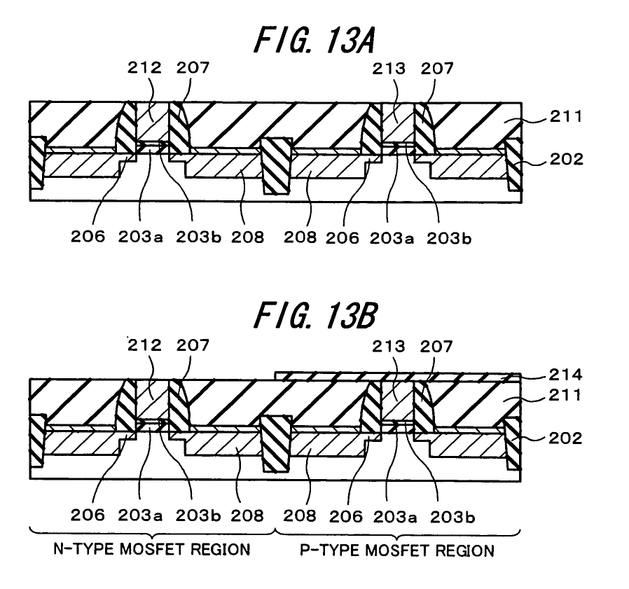

Further, after the unreacted metal film 210 is removed (FIG. 12B), an interlayer insulating film 211 of silicon oxide film is formed on the entire surface by the CVD method as shown in FIG. 12C. Next, the interlayer insulating film 211 is flattened by the CMP (Chemical Mechanical Polishing) technique and further, by carrying out the etch-back of the interlayer insulating film 211 and the mask 205, the poly-Si 212, 213 constituting the first and second gate patterns are exposed (FIG. 13A).

Next, a diffusion preventive layer (mask) 214 is deposited on the entire surface including the upper surfaces of the first gate pattern 212 and the second gate pattern 213. After that, using the lithography technique and the RIE technique, by removing the diffusion preventive layer present on at least the first gate pattern 212, the first gate pattern 212 is exposed. As a result, the diffusion preventive layer 214 (second mask) is formed so as to cover the second gate pattern 213 (FIG. 13B).

The purpose of the formation of the diffusion preventive layer (second mask) 214 is to prevent the second gate pattern 213 and the metal atom from reacting each other to form a silicide layer when forming the first gate electrode of the silicide (A) by silicidating the first gate pattern 212. As the material of the diffusion preventive layer 214, it is necessary to select one which can prevent the diffusion of metal relating to the silicidation in the silicidation process and which itself is stable. Further, it is preferable for the material of the diffusion preventive layer to be one that can be selectively etched for the metal to be silicidated and the interlayer insulating film.

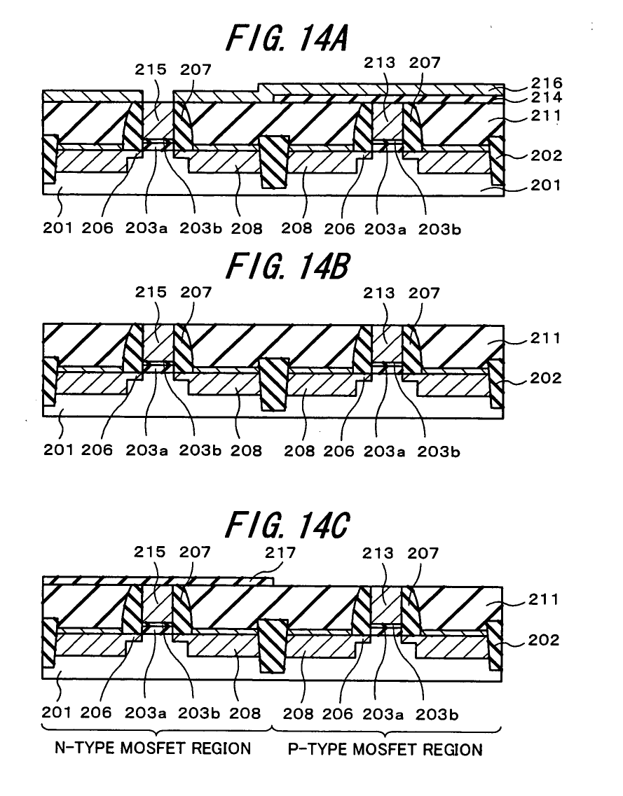

Next, those formed as described above are introduced into the manufacturing apparatus of a semiconductor device and the material gas containing the first metal that can be used to form a silicide with polysilicon constituting the first gate pattern 212 is supplied into the apparatus. Then, the first gate pattern 212 is heated to a temperature at which the material gas thermally decomposes and under the conditions that the layer of the first metal does not deposit on the first gate pattern 212, the first metal is reacted with the polysilicon. As a result, without the deposition of the metal layer, the first gate pattern 212 can be turned into the first gate electrode 215 constituted by the first metal silicide (A) (formation process of N-type MOSFET gate electrode: first silicidation process). FIG. 14A shows a state where the first gate electrode is formed in this manner. In this state, the material gas is supplied in such a manner that the metal layer does not deposit on the surface of the first gate pattern 212 (because all of the supplied metal atoms are consumed in forming silicide), and therefore, no metal layer has deposited on a first gate electrode 215 that is formed. On the other hand, as to the parts other than the surface of the first gate electrode 215, the metal atoms are not consumed in forming silicide, and therefore, a metal film 216 in which the supplied metal atoms have deposited without being consumed is formed as a result.

Next, as shown in FIG. 14B, by wet etching using the sulfuric acid hydrogen peroxide solution, the diffusion preventive layer (second mask) 214 and the metal layer 216 are removed. After that, a diffusion preventive layer 217 is deposited on the entire surface including the exposed part of the second gate pattern 213 and using the lithography technique and the RIE technique, at least the diffusion preventive layer 217 deposited on the second gate pattern 213 is removed and thus the second gate pattern 213 is exposed. As a result, the diffusion preventive layer 217 (first mask) is formed so as to cover the first gate electrode 215 (FIG. 14C).

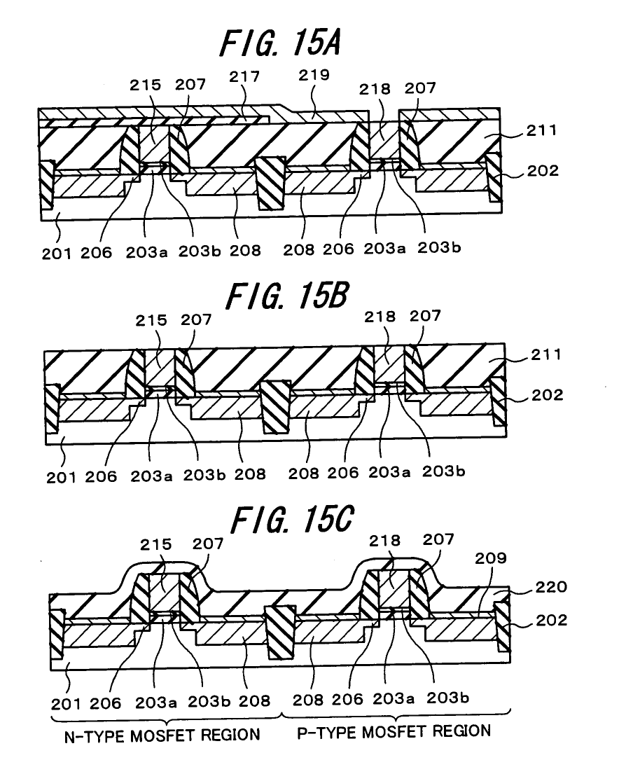

After that, in order to silicidate the second gate pattern 213, the device shown in FIG. 14C is introduced into the manufacturing apparatus of a semiconductor device. After that, a material gas containing the first metal that can be used to form a silicide with polysilicon constituting the second gate pattern 213 is supplied, the second gate pattern 213 is heated to a temperature at which the material gas thermally decomposes, and the first metal and the polysilicon are caused to react with each other under the conditions that the layer of the first metal does not deposit on the second gate pattern 213. Then, the second gate pattern 213 is turned into a second gate electrode 218 constituted by the silicide (B) of the first metal (formation process of P-type MOSFET gate electrode: second silicidation process: FIG. 15A).

Next, as shown in FIG. 15B, by wet etching using the sulfuric acid hydrogen peroxide solution, the diffusion preventive layer (first mask) 217 and a metal layer 219 are removed. Here, with the manufacturing method of a semiconductor device according to the present invention, it is possible to form the silicides (A), (B) having the same composition as the first gate electrode and the second gate electrode by making the formation conditions of the first silicidation process equal to those of the second silicidation process. In this case, the first and second silicidation processes may be carried out simultaneously, instead of carrying out them separately.

It is also possible to form the silicides (A), (B) having different compositions as the first gate electrode and the second gate electrode by making the formation conditions of the first silicidation process different from those of the second silicidation process.

In the above-described explanation, the semiconductor device is manufactured in the order of the processes of the formation of the second mask onto the second gate pattern after the first and second gate patterns are exposed, the first silicidation, the removal of the second mask and metal layer, the formation of the first mask onto the first gate electrode, the second silicidation, and the removal of the first mask and metal layer. However, according to the manufacturing method of the present invention, the order of the first silicidation and the second silicidation is not limited in particular and the first silicidation may be carried out first, or the second silicidation may be carried out first. For example, when the second silicidation is carried out first, in the manufacturing method of the present invention, the semiconductor device is manufactured in the order of the processes of the formation of the first mask onto the first gate pattern after the first and second gate patterns are exposed, the second silicidation, the removal of the first mask and metal layer, the formation of the second mask onto the second gate electrode, the first silicidation, and the removal of the second mask and metal layer.

Further, after that, as shown in FIG. 15C, after the interlayer insulating film 211 is removed by etching, a silicon nitride film 220 can be formed. For the etching of the interlayer insulating film 211, wet etching using the HF aqueous solution or dry etching can be used, however, for the suppression of the plasma damage to the gate electrode, it is preferable to use wet etching using HF.

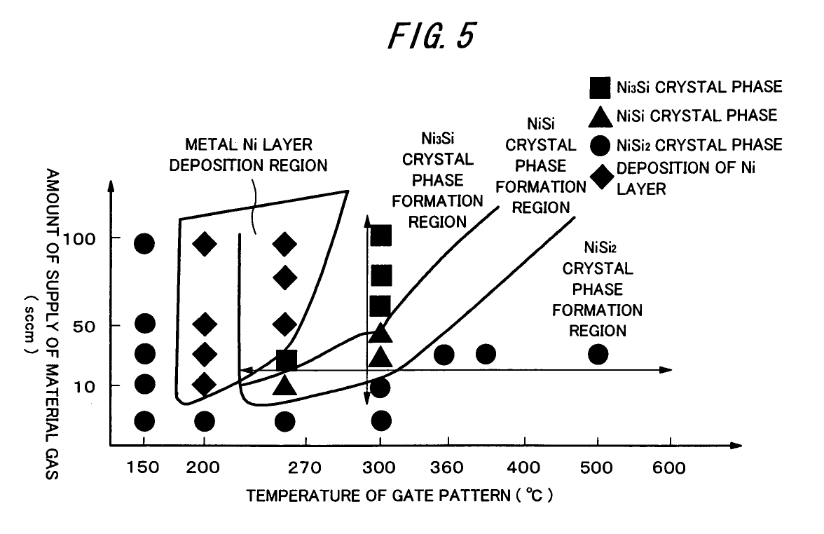

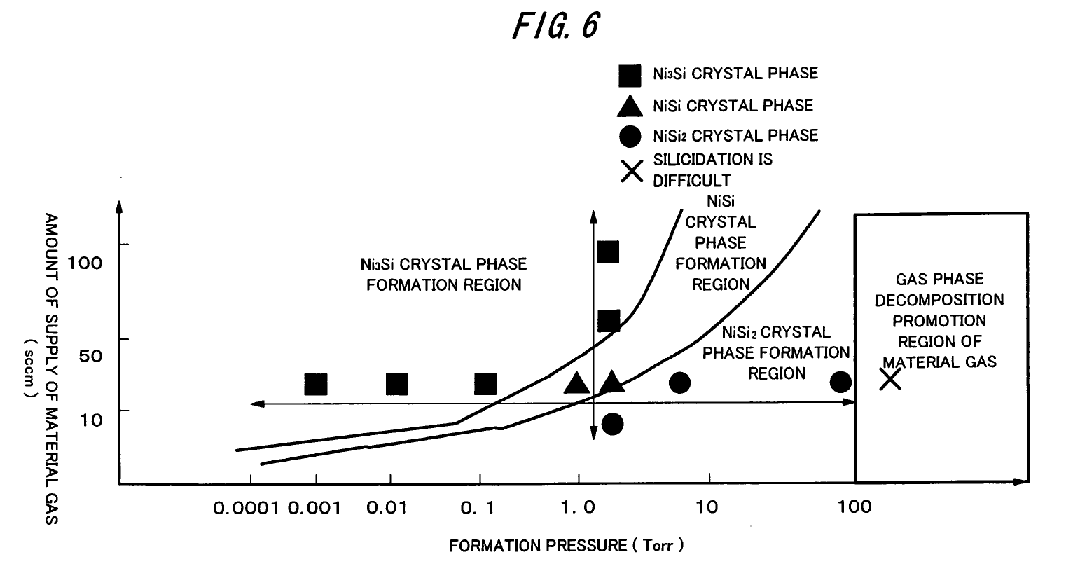

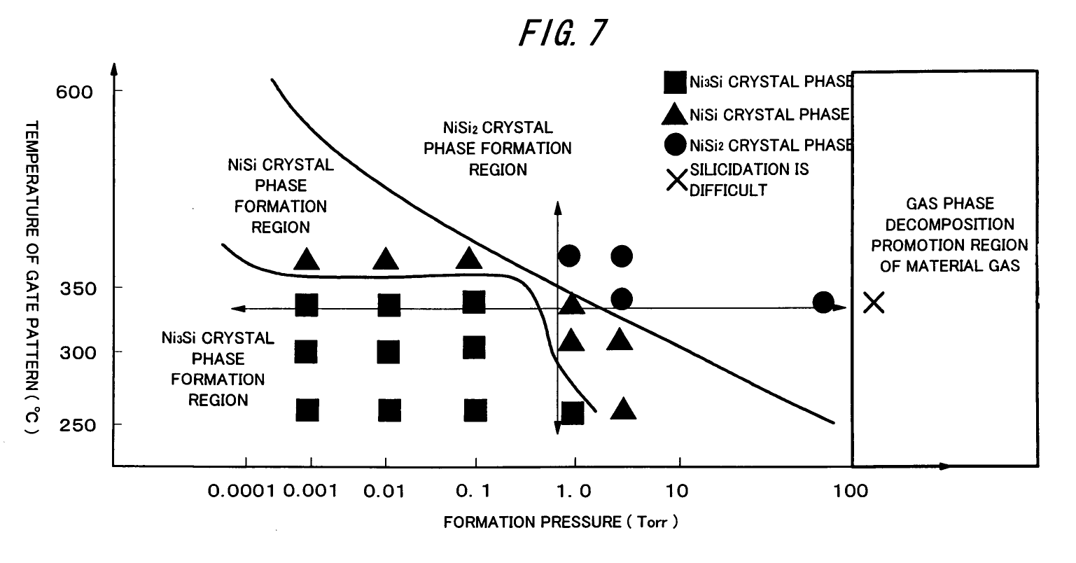

Through the above-described processes, it is possible to form the N-type MOSFET gate electrode (first gate electrode) and the P-type MOSFET gate electrode (second gate electrode) in a small number of processes and by low-temperature processing. Further, it is possible to control the composition of the first and second electrodes to a desired even composition. Furthermore, by making the conditions for the first silicidation process differ from those for the second silicidation process, it is possible to form a semiconductor device in which the composition of the first gate electrode is different from that of the second electrode. For example, as the formation conditions of the silicide layers of the first and second gate electrodes, the optimum conditions can be selected and executed, respectively, from the conditions shown in FIG. 5, FIG. 6, FIG. 7 for the amount of supply of material gas, the temperature of gate pattern, and the formation pressure.

(Formation Process of Gate Electrode: First and Second Silicidation Processes)

The first and second silicidation processes may be carried out simultaneously or separately. Further, either silicidation process of the first and second silicidation processes may be carried out first. For example, when a semiconductor device is manufactured, in which the first and second gate electrodes are constituted by the silicide having the same configuration/crystal phase but different kinds of impurity element contained in the silicide, the first and second silicidation processes may be carried out simultaneously.

On the other hand, when a semiconductor device is manufactured, in which the first and second gate electrodes are constituted by the silicides having different composition/crystal phases from each other, as the conditions for the first and second silicidation processes, the following conditions can be set.

(1) Preferably, the silicide layer is formed under the conditions that the amount of supply of the material gas is larger in the formation conditions in the second silicidation process than in the formation conditions in the first silicidation process. By forming the first and second gate electrodes under these conditions, it is possible to form a silicide layer having a higher metal element content ratio than that in the silicide (A) of the first gate electrode as the silicide (B) of the second gate electrode.

(2) Preferably, the silicide layer is formed under the conditions that the temperature of the gate pattern is lower in the formation conditions in the second silicidation process than in the formation conditions in the first silicidation process. By forming the first and second gate electrodes under these conditions, it is possible to form the silicide layer having a higher metal element content ratio than that in the silicide (A) of the first gate electrode as the silicide (B) of the second gate electrode.

(3) Preferably, the silicide layer is formed under the conditions that the formation pressure is lower in the formation conditions in the second silicidation process than in the formation conditions in the first silicidation process. By forming the first and second gate electrodes under these conditions, it is possible to form the silicide layer having a higher metal element content ratio than that in the silicide (A) of the first gate electrode as the silicide (B) of the second gate electrode.

When the interlayer insulating film 211 is removed by wet etching using the HF aqueous solution in the last process (corresponding to the process in FIG. 15C), it is necessary for the gate electrode to have etching resistant property against the HF aqueous solution. In this case, it is preferable that the silicide layer having a Ni-rich composition be exposed on the top of the gate electrode.

According to the manufacturing method of a semiconductor device of the present invention, it is made possible to change the metal composition in the direction of film thickness of the gate electrode by changing the conditions for silicidation in the middle of the silicidation process. As a result, it is made possible to form a silicide layer having the HF resistant property on top of the gate electrode.

For example, when a silicide layer constituted by the NiSi₂ crystal phase is formed as the first gate electrode, NiSi₂ elutes in the wet etching process using the I-IF aqueous solution described above and the function as the gate electrode is deteriorated. In contrast to this, by adopting a laminated structure in which the NiSi₂ crystal phase is formed as the first silicide layer and the NiSi crystal phase is formed as the second silicide layer on the first silicide layer, the resistant property against the wet etching using the HF aqueous solution can be reserved. As for the modification of the silicidation conditions in the middle of the silicidation process, only the conditions for the first silicidation process may be modified, or only those for the second silicidation process may be modified, or those for both the first and the second silicidation processes may be modified.

(Relationship Between Gate Electrode Composition and Formation Conditions)

The relationship between the gate electrode composition and the formation conditions of the present invention is shown below.

FIG. 5 roughly shows the relationship between the composition of a silicide layer, the amount of supply of the Ni material (material gas; Ni(PF₃)₄), and the temperature of the gate pattern when the formation pressure (the total pressure in the reaction container in which an object to be processed is placed at the time of the formation of electrode gate: the total pressure of the material gas and the carrier gas when the gas supplied into the reaction container is the material gas and the carrier gas: the atmospheric pressure at the time of silicidation) is kept fixed. Here, the flow rate of the carrier gas (N₂) is set to 100 sccm and the pressure is set fixed at 2.5 Torr. For example, in FIG. 5, when the temperature of gate pattern is 300° C., as the amount of supply of the Ni material gas increases, a silicide layer is formed that has the composition/crystal phase in which the number of Ni atoms increases, that is, the crystal phase of the silicide layer changes from the NiSi₂ crystal phase to the NiSi crystal phase and the Ni₃Si crystal phase in this order (the compositions on the line parallel to the vertical axis in FIG. 5). The reason for the change of the composition of the silicide layer toward the Ni-richer side as the amount of supply of the Ni material gas increases is that the number of Ni atoms that are adsorbed onto the gate pattern increases.

Similarly, when the amount of supply of the material gas is fixed, it is also possible to form a silicide layer having the composition/crystal phase in which the number of Si atoms increases as the temperature of gate pattern increases, that is, the composition of the silicide changes from the Ni₃Si crystal phase to the NiSi crystal phase and the NiSi₂ crystal phase in this order (the compositions on the line parallel to the horizontal axis in FIG. 5). The reason for the change of the composition of the silicide layer toward the Si-richer side as the temperature of gate pattern increases is that the molecule motion of the Ni atoms that have been adsorbed to the surface of the gate pattern becomes more active as the temperature of the gate pattern increases and it becomes easier for the Ni atom to be desorbed from the surface of the gate pattern.

Further, in FIG. 5, in the region where the temperature of gate pattern is between 200° C. to 300° C., when the amount of supply of the material gas increases, the deposited layer of the metal Ni layer is formed on the gate pattern of the poly-Si and there exists a region where the control of the composition/crystal phase of the silicide layer becomes difficult. The metal Ni layer deposits on the poly-Si in this manner because the number of Ni atoms adsorbed onto the poly-Si becomes larger than the number of Ni atoms adsorbed onto the poly-Si and consumed for the formation of the silicide layer.

From the above, when the temperature of gate pattern is lower than the temperature at which the material gas thermally decomposes on the surface of the gate pattern, the metal atoms used as the material of silicide are not supplied and therefore, silicidation does not take place. If the temperature of gate pattern is high, the metals that have been adsorbed to the surface of the gate pattern are desorbed from the surface and therefore the formation rate of the silicide layer is reduced. Consequently, it is necessary to set the temperature of gate pattern to a temperature higher than or equal to the temperature at which the material gas thermally decomposes and lower than or equal to the temperature at which the number of metal atoms that are adsorbed and the number of metal atoms that are desorbed therefrom are equal on the surface of the exposed gate pattern. Specifically, it is preferable for the heating temperature of the gate pattern to be in the range no less than 150° C. and no more than 600° C. Further, it is preferable to set the temperature to a temperature or less at which the resistance value of the silicide layer already formed on the source/drain diffusion layer region will not increase any more. Specifically, it is much preferable to set the temperature of gate pattern no less than 150° C. and no more than 500° C.

FIG. 6 shows the relationship between the composition of silicide layer, the amount of supply of the Ni material gas (Ni(PF₃)₄), and the formation pressure (the pressure in the reaction container of the manufacturing apparatus of a semiconductor device: the atmospheric pressure in the container at the time of silicidation). Here, the flow rate of the carrier gas (N₂) is set 100 sccm and the temperature is kept fixed at 300° C. It is possible to change the amount of supply of the material gas by adjusting the flow rate of the supply system of the material gas. It is also possible to change the formation pressure by adjusting the flow rate of the material gas or the material gas and the carrier gas to be discharged in the discharge system of the manufacturing apparatus (the degree of opening of the discharge valve of the reaction container etc.). FIG. 6 shows that, when the temperature of the gate pattern and the amount of supply of the Ni material gas are fixed and if the formation pressure is increased, a silicide layer is formed that has the composition/crystal phase in which the number of Si atoms increases, that is, the crystal phase changes form the Ni₃Si crystal phase to the NiSi crystal phase and the NiSi₂ crystal phase in this order (the compositions on the line parallel to the horizontal axis in FIG. 6). This is because the speed of the movement of the Ni atom on the poly-Si gate pattern increases when the formation pressure increases and it becomes more difficult for the Ni atom to be adsorbed to the surface of the gate pattern.

If the formation pressure is high, there may be a case where the decomposition of the material in the gas phase is promoted and elements other than Ni that constitutes the material gas are adsorbed onto the gate pattern, and thus, the silicidation reaction is suppressed and the formation rate of the silicide layer is reduced. Consequently, the lower the formation pressure, the less susceptible to such an influence, and therefore, the adsorption of Ni onto the gate pattern of the poly-Si and the silicidation reaction are promoted. From this, it is preferable for the formation pressure to be 100 Torr or less and further, it is much preferable to form the silicide layer at 10 Torr or less by causing the decomposition reaction to take place only by the thermal excitation on the substrate surface while not causing the material gas to decompose in the gas phase.

On the other hand, in FIG. 6, when the temperature of the gate pattern and the formation pressure are fixed, if the amount of supply of the Ni material gas is increased, it is possible to form a silicide layer having the composition/crystal phase in which the amount of Ni increases, that is, the crystal phase changes from the NiSi₂ crystal phase to the NiSi crystal phase and the Ni₃Si crystal phase in this order (the compositions on the line parallel to the vertical axis in FIG. 6). This is because, as the amount of supply of the Ni material gas increases, the number of the Ni atoms that are adsorbed onto the gate pattern of poly-Si and involved in the silicidation increases.

FIG. 7 shows the relationship between the composition of silicide layer, the temperature of gate pattern, and the formation pressure when the amount of supply of the Ni material gas (Ni(PF₃)₄) is kept fixed. Here, the flow rate of the carrier gas (N₂) is set to 100 sccm and the amount of supply of the Ni material is kept fixed at 20 sccm. The formation pressure is adjusted as in FIG. 6. From FIG. 7, when the amount of supply of the Ni material gas and the formation pressure are kept fixed and the temperature of gate pattern is increased, the composition changes from the Ni₃Si crystal phase to the NiSi crystal phase and the NiSi₂ crystal phase, that is, the amount of Si increases (the compositions on the line parallel to the vertical axis in FIG. 7). In FIG. 7, when the temperature of the gate pattern and the amount of supply of the Ni material gas are fixed and if the formation pressure is increased, it is possible to form a silicide layer having the composition/crystal phase in which the amount of Si becomes larger, that is, the crystal phase changes from the Ni₃Si crystal phase to the NiSi crystal phase and the NiSi₃ crystal phase in this order (the compositions on the line parallel to the horizontal axis in FIG. 7).

As shown in FIGS. 5 to 7, it is possible to manufacture a gate electrode having even NiSi₂, NiSi, and Ni₃Si crystal phases, respectively, as the gate electrode of the N-type MOSFET and the P-type MOSFET by optimizing the temperature of gate pattern, the formation pressure, and the amount of supply of material gas. Consequently, it is possible to manufacture a semiconductor device in which the gate electrode of each MOSFET is a silicide layer having a desired composition by adjusting these manufacture conditions (the temperature of gate pattern, the formation pressure, and the amount of supply of material gas). This is because the amount of Ni that are adsorbed to the surface of poly-Si is associated with the temperature of gate pattern, the formation pressure, and the amount of supply of material gas.

(Control of Composition in Direction of Film Thickness of Gate Electrode)

Further, according to the manufacturing method of a semiconductor device of the present invention, during the period in which at least one silicidation process of the first and second silicidation processes is being carried out, it is possible to form a gate electrode from a plurality of silicide layers different in composition and properties by changing the formation conditions of the silicide layer. The aspect where the formation conditions of the silicide layer are changed in the middle of the silicidation process is explained below.

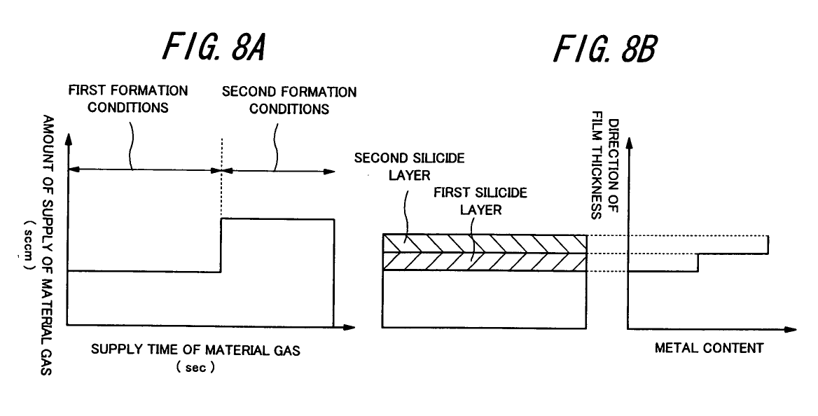

(1) As shown in FIG. 8A, it may also be possible to form the gate electrode by forming the first silicide layer under the first formation conditions and then forming the second silicide layer on the top of the first silicide layer under the second formation conditions when the first silicide layer reaches a predetermined film thickness. At this time, the silicide layer is formed under conditions that at least the amount of supply of the material gas (material gas containing the metal that can be used to form the silicide layer) is larger in the second formation conditions compared to that in the first formation conditions. With the arrangement, as shown in FIG. 8B, it is made possible to change the amount of metal element contained in the silicide layer in the direction of film thickness of the gate electrode (to reduce the metal content toward the side of the gate insulating film in the direction of film thickness (in the direction of the normal of the gate electrode)).

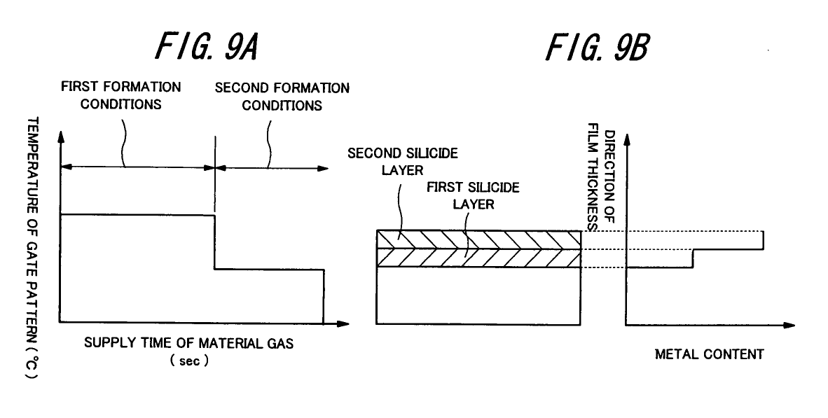

(2) As shown in FIG. 9A, it may also be possible to form the gate electrode by forming the first silicide layer under the first formation conditions and then forming the second silicide layer on the top of the first silicide layer under the second formation conditions when the first silicide layer reaches a predetermined film thickness. At this time, the silicide layer is formed under conditions that at least the temperature of the gate pattern is lower in the second formation conditions compared to that in the first formation conditions. With the arrangement, as shown in FIG. 9(b), it is made possible to change the amount of metal element contained in the silicide layer in the direction of film thickness of the gate electrode (to reduce the metal content toward the side of the gate insulating film in the direction of film thickness (in the direction of the normal of the gate electrode)).

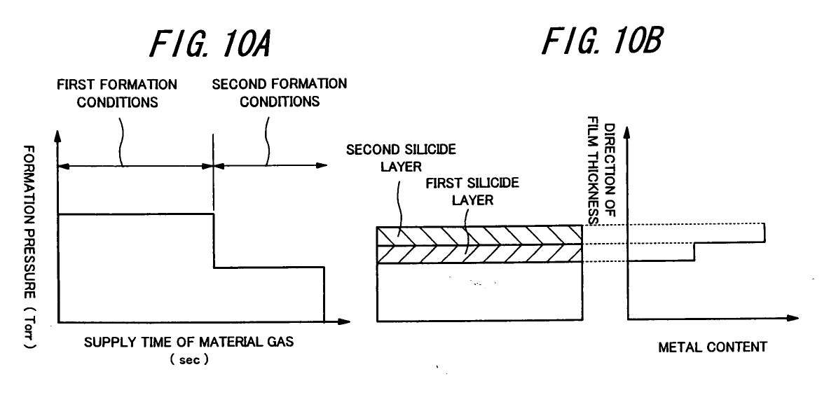

(3) As shown in FIG. 10A, it may also be possible to form the gate electrode by forming the first silicide layer under the first formation conditions and then forming the second silicide layer on the top of the first silicide layer under the second formation conditions when the first silicide layer reaches a predetermined film thickness. At this time, the silicide layer is formed under conditions that at least the formation pressure is lower in the second formation conditions compared to that in the first formation conditions. With the arrangement, as shown in FIG. 10(b), it is made possible to change the amount of metal element contained in the silicide layer in the direction of film thickness of the gate electrode (to reduce the metal content toward the side of the gate insulating film in the direction of film thickness (in the direction of the normal of the gate electrode)).

As described above, it is possible to form a structure having the first and second silicide layers different in the composition/crystal layer in the direction of film thickness of the gate electrode by continuously changing the formation conditions of the silicide layer. In terms of the process resistant property against the etching process etc., it is preferable that the amount of metal element contained in the second silicide layer formed under the second formation conditions be larger than the amount of metal element contained in the first silicide layer formed under the first formation conditions.

For example, the amount of supply of material gas, the temperature of gate pattern, and the formation pressure of the formation conditions of the first silicide layer and the formation conditions of the second silicide layer can be selected and executed from the optimum conditions shown in FIG. 5, FIG. 6, FIG. 7.

The silicidation divided into two stages as in (1) to (3) described above (FIGS. 8 to 10) may be carried out both in the first and the second silicidation processes, or may be carried out in either of the processes. Further, when silicidation divided into two stages is carried out in both the first and the second silicidation processes, silicidation may be carried out so that the composition/film thickness distribution of the first and second gate electrodes are the same or so that they are different.

(Material Gas)

In terms of the resistance value and work function, it is preferable for the first metal contained in the material gas to be at least one kind of metal selected from a group consisting of Ni, Pt, Co, W, and Ru. If C is contained in the material gas, C is adsorbed onto the surface of the gate pattern and the silicidation reaction is suppressed. Consequently, it is preferable for C not to be contained in the material gas.

Further, it is preferable for the material gas to contain at least one kind of gas selected from a group consisting of Ni(PF₃)₄, Ni(BF₂)₄, Pt(PF₃)₄, Pt(BF₂)₄, Co(PF₃)₆, Co(BF₂)₆, W(PF₃)₆, W(BF₂)₆, Ru(PF₃)₅, and Ru(BF₂)₅.

(Silicidation Conditions of Gate Electrode)

The relationship between the gate electrode silicidation conditions (the temperature of gate pattern, the formation pressure, the amount of supply of material gas) and the composition of silicide to be formed when Ni(PF₃)₄ or Ni(BF₂)₄ is used as the material gas is shown below. When the material gas is Ni(PF₃)₄ or Ni(BF₂)₄, it is possible to form a silicide layer having any crystal phase of the NiSi₂ crystal phase, the NiSi crystal phase, and the Ni₃Si crystal phase by changing the silicidation conditions.

(1) When the material gas is Ni(PF₃)₄ or Ni(BF₂)₄, as shown in FIG. 5, FIG. 6, FIG. 7, it is preferable for the temperature of the gate pattern to be no less than 150° C. and no more than 600° C. in order to form a silicide layer having the NiSi₂ crystal phase. On the other hand, in the region where the temperature of the gate pattern is less than 250° C., because the thermal decomposition reaction of the material gas on the surface of the gate pattern is suppressed, there may be a case where the formation rate of the silicide layer is reduced. Further, in the region where the temperature of gate pattern exceeds 400° C., because the metal components that are desorbed from the top of the gate pattern increase in number, there may be a case where the formation rate of the silicide layer is reduced. Consequently, it is preferable for the temperature of the gate pattern to be no less than 250° C. and no more than 400° C.

Further, it is preferable for the formation pressure to be 100 Torr or less in order to suppress the components of gas phase decomposition of the material gas and it is much preferable for that to be no less than 1×10⁻⁴ Torr and no more than 10 Torr in order to cause the decomposition of the material gas only on the surface of the gate pattern and the controllability of the silicide crystal phase by the amount of supply of the material gas to coexist. In particular, in the present invention, the NiSi₂ crystal phase is formed at a temperature less than or equal to 300° C., which is further lower than that in the prior art, by setting such formation conditions, and thus it is indicated that the present invention is suitable to reduce the formation temperature of a silicide.

(2) When the material gas is Ni(PF₃)₄ or Ni(BF₂)₄, as shown in FIG. 5, FIG. 6, and FIG. 7, it is preferable for the temperature of the gate pattern to be no less than 250° C. and no more than 600° C. in order to form a silicide layer having the NiSi composition/crystal phase. On the other hand, in the region where the temperature of the gate pattern exceeds 400° C., because the Ni components that are desorbed from the gate pattern increase in number, there may be a case where the formation rate of the silicide layer is reduced. Consequently, it is much preferable for the temperature of the gate pattern to be no less than 250° C. and no more than 400° C.

Further, it is preferable for the formation pressure to be 80 Torr or less in order to suppress the components of gas phase decomposition of the material gas and it is much preferable for that to be no less than 1×10⁻⁴ Torr and no more than 10 Torr in order to cause the decomposition of the material gas only on the surface of the gate pattern and the controllability of the silicide crystal phase by the amount of supply of the material gas to coexist.

(3) When the material gas is Ni(PF₃)₄ or Ni(BF₂)₄, as shown in FIG. 5, FIG. 6, and FIG. 7, it is preferable for the temperature of the gate pattern to be no less than 250° C. and no more than 500° C. in order to form a silicide layer having the Ni₃Si crystal phase. On the other hand, in the region where the temperature of the gate pattern exceeds 400° C., because the Ni components that are desorbed from the gate pattern increase in number, there may be a case where the formation rate of the silicide layer is reduced. Consequently, it is much preferable for the temperature of the gate pattern to be no less than 250° C. and no more than 400° C.

Further, it is preferable for the formation pressure to be 10 Torr or less in order to suppress the components of gas phase decomposition of the material gas and it is much preferable for that to be no less than 1×10⁻⁴ Torr and no more than 5 Torr in order to cause the decomposition of the material gas only on the surface of the gate pattern and the controllability of the silicide crystal phase by the amount of supply of the material gas to coexist.

(4) When the material gas is Ni(PF₃)₄ or Ni(BF₂)₄, it is possible to form the first silicide layer having the NiSi₂ crystal phase under the first formation conditions and to form the second silicide layer having at least one crystal phase of the NiSi and Ni₃Si crystal phases under the second formation conditions. By forming a gate electrode having such a composition, a gate electrode excellent in etching resistance can be formed.

(5) When the material gas is Ni(PF₃)₄ or Ni(BF₂)₄, it is possible to form a silicide layer having at least one crystal phase of the NiSi and Ni₃Si crystal phases as the other gate electrode after forming a silicide layer having the NiSi crystal phase as one gate electrode. By forming a gate electrode having such a composition, it is possible to effectively control Vth of the MOSFET having these gate electrodes.

(6) When the material gas is Ni(PF₃)₄ or Ni(BF₂)₄, it is possible to form the first silicide layer having the NiSi₂ crystal phase as one gate electrode and then to form the second silicide layer having the NiSi crystal phase thereon. Further, it is possible to form a silicide layer having the Ni₃Si crystal phase as the other gate electrode. By forming a gate electrode having such a composition, it is possible to form a gate electrode excellent in the etching resistance and at the same time, to effectively control Vth of the MOSFET having these gate electrodes.

(Manufacturing Apparatus of Semiconductor Device)

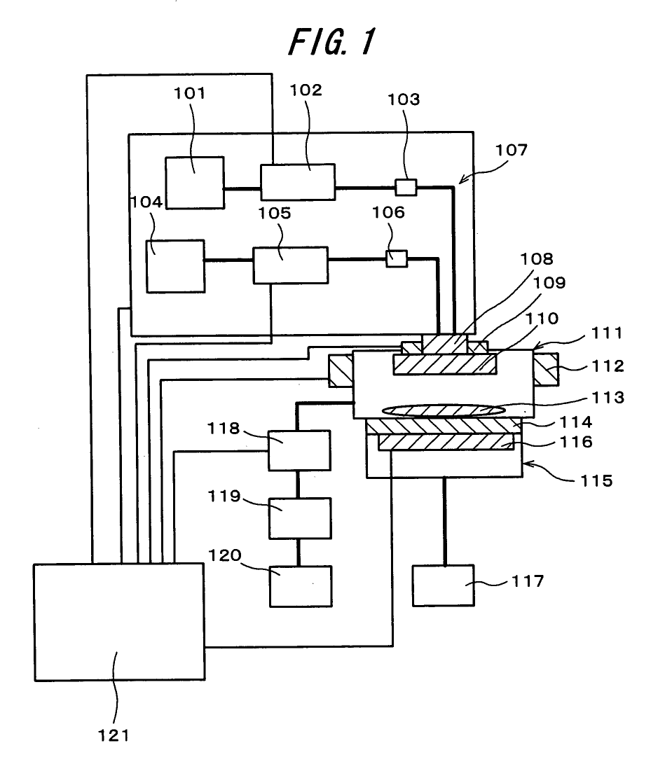

A configuration of an example of a manufacturing apparatus used in an embodiment of the present invention is shown in FIG. 1. In this apparatus, first, the flow rate (amount of supply) of a material gas including the first metal that can be used to form a silicide layer is adjusted to a predetermined one by a material gas source 101 via a mass flow controller 102 and the material gas is supplied into a vacuum container 111 via a valve 103, a gas introduction inlet 108, and a shower head 110.

The flow rate of a carrier gas is adjusted to a predetermined one by a carrier gas source 104 via a mass flow controller 105, and the carrier gas is supplied into the vacuum container 111 through a valve 106, the gas introduction inlet 108, and the shower head 110.

The material gas may be supplied into the vacuum container 111 alone or along with the carrier gas. Further, when the material gas is not supplied into the vacuum container 111, the carrier gas may be used as a replacement gas. As the carrier gas, it is preferable to use an inert gas that does not react with the material gas and to contain at least one kind of gas selected from a group consisting of N₂, Ar, and He.

In this apparatus, the carrier gas source 104, the mass flow controller 105, and the valve 106 are controlled to the same temperature as that of the metal material gas by a thermostat chamber 107 so that they do not affect the temperature of the material gas when coming into contact with the material gas.

It is preferable for the temperature of the thermostat chamber 107 to be controlled to no less than 0° C. and no more than 150° C. The material introduction inlet 108, the shower head 110, and the vacuum container 111 are controlled by a heater 109 and a heater 112 to a temperature higher than or equal to the temperature at which the material gas has an enough vapor pressure and lower than or equal to the temperature of the decomposition of the material gas. It is preferable that this temperature be no less than 0° C. and no more than 150° C.

Within the vacuum container 11, a substrate (structure in which the interlayer insulating film is removed and at least one of the first and second gate patterns is exposed; for example, a structure in FIG. 13(b) etc.) 113 is provided and is heated to a predetermined temperature (temperature at which the material gas thermally decomposes on the substrate surface) by a heater 116 via a susceptor 114.

The pressure in the vacuum container 111 is controlled by the degree of opening of a conductance valve 118.

In the manufacturing apparatus of a semiconductor device, the thermostat chamber 107, the mass flow controllers 102 and 105, the heaters 109, 112, and 116, and the conductance valve 118 are connected to a control part 121 and controlled by the control part under the conditions that a metal layer does not deposit on the exposed gate pattern on the substrate, respectively.

More specifically, the control part is designed to input in advance the conditions that a metal layer does not deposit on the gate pattern as the characteristic value of each part described above and to issue an instruction to each part so that the characteristic value input in advance be restored when the characteristic value of each part deviates from that which is input in advance during the operation of the above-described apparatus. Due to the instruction of the control part, the characteristic value of each part is maintained to be a predetermined characteristic value.

Further, the characteristic value of each part can be changed two or more times during the operation of the apparatus. In this case, the control part issues an instruction to each part to change the formation conditions while the silicide layer is being formed by inputting in advance so that the control part changes the formation conditions of the silicide layer during the operation of the apparatus. Then, by changing the formation conditions of the silicide layer during the operation, it is made possible to form silicide layers with a plurality of compositions and different characteristics.

### EMBODIMENTS

### First Embodiment

FIG. 11 to FIG. 15 are cross-sectional views showing manufacturing processes of a semiconductor device in the present embodiment. First, the silicon substrate 201 having the N-type region (N-type active region; N well) 251 and the P-type region (P-type active region; P well) 252 is prepared. Next, the element isolation region 202 is formed so that the N-type region 251 and the P-type region 252 are insulated and isolated (element isolation) using the STI (Shallow Trench Isolation) technique on the surface region of the silicon substrate 201. Subsequently, the silicon oxide film 203a (gate insulating film) having a thickness of 1.9 nm and the HfSiON film 203b (gate insulating film) having a thickness of 1.5 nm are formed on the surface of the silicon substrate 201 on which elements have been isolated. The silicon oxide film 203a is manufactured by thermal oxidation of silicon. The HfSiON film 203b is manufactured using the CVD method and then by annealing with nitrogen in the NH₃ atmosphere at 900° C. for ten minutes.

Next, a laminated film consisting of the poly-Si film (polysilicon film) 204 having a film thickness of 60 nm and the silicon oxide film 205 having a film thickness of 150 nm is formed on the gate insulating film formed as described above (FIG. 11A). By using the lithography technique and the RIE (Reactive Ion Etching) technique for the laminated film as shown in FIG. 11(b), the first gate pattern 212 and the mask 205 are provided on the P-type region 252 and the second gate pattern 213 and the mask 205 are provided on the N-type region 251, respectively (first formation process).

Subsequently, a mask (not shown) is provided on the P-type region 252, ions are implanted using the mask and the mask 205 as a mask, and the extension diffusion layer region 206 is formed in a self-alignment manner in the N-type region 251. Then, after the mask provided on the P-type region 252 is removed, a mask (not shown) is provided on the N-type region 251, ions are implanted using the mask and the mask 205 as a mask, and the extension diffusion layer region 206 is formed in a self-alignment manner in the P-type region 252.

Further, the silicon nitride film and the silicon oxide film are deposited sequentially and then, the gate sidewall 207 is formed on both side surfaces of the gate insulating films 203a and 203b, the second gate pattern 213, and the mask 205, and on both side surfaces of the gate insulating films 203a and 203b, the first gate pattern 212, and the mask 205, respectively, by carrying out etch-back. Next, a mask (not shown) is provided on the P-type region 252 and using the mask, the mask 205, and the gate sidewall 207 as a mask, ions are implanted.

Then, after the mask provided on the P-type region 252 is removed, a mask (not shown) is provided on the N-type region 251 and using the mask, the mask 205, and the gate sidewall 207 as a mask, ions are implanted. After that, through the activation annealing, the source/drain region 208 is formed in the N-type region 251 and the P-type region 252, respectively (FIG. 11C: second formation process).

Next, as shown in FIG. 12A, the Ni metal film 210 having a film thickness of 20 nm is deposited on the entire surface and using the gate electrode, the gate sidewall, and STI as a mask, the Ni silicide layer 209 having a film thickness of 40 nm is formed only on the source/drain region 208 by the salicide technique. After that, the unreacted metal film 210 is removed as shown in FIG. 12(b).

Further, the interlayer insulating film 211 of silicon oxide film is formed by the CVD method as shown in FIG. 12C. Next, the interlayer insulating film 211 is flattened by the CMP (Chemical Mechanical Polishing) method and further, by carrying out etch-back, the interlayer insulating film 211 and the mask 205 are removed, and thus the second gate pattern 213 and the first gate pattern 212 are exposed (FIG. 13A).

Next, after TiN having a thickness of 20 nm is deposited so as to cover the exposed second gate pattern 213 by the reactive sputtering method, the TiN that has deposited on the first gate pattern 212 is removed by the use of the lithography technique and the RIE (Reactive Ion Etching) technique, and thus the second mask 214 is provided so as to remain on the second gate pattern 213 (FIG. 13(b)).

Next, the structure in FIG. 13(b) is set in the manufacturing apparatus in FIG. 1. Then, Ni(PF₃)₄ containing Ni(first metal) is supplied at 2 sccm into the reaction container of the manufacturing apparatus, and as the carrier gas, N₂ is supplied at 100 sccm for 45 minutes. Then, the total gas pressure of the material gas and the carrier gas in the reaction container for silicidation is controlled to be 2.5 Torr. In this state, polysilicon constituting the first gate pattern 212 is heated to a temperature of 300° C. at which the material gas thermally decomposes.

Then, the first metal and polysilicon are reacted with each other and thus the first gate pattern 212 is turned into the first gate electrode 215 constituted by NiSi₂(silicide (A)) (first silicidation process; FIG. 14A). At this time, the deposition of the Ni film onto the first gate pattern 212 is not confirmed. After that, the unreacted metal layer 216 that has deposited on parts other than the second mask 214 and the first gate electrode 215 is removed by wet etching using the sulfuric acid hydrogen peroxide solution (FIG. 14(b)).

Next, after TiN having a thickness of 20 nm is deposited on the entire surface by the reactive sputtering method, the first mask 217 is formed so as to remain on the first gate electrode 215 by removing TiN that has been deposited on the second gate pattern 213 using the lithography technique and the RIE (Reactive Ion Etching) technique (FIG. 14C).

After that, Ni(PF₃)₄ containing Ni(first metal) is supplied at 80 sccm, and as the carrier gas, N₂ is supplied at 100 sccm for 20 minutes. Then, the total gas pressure of the material gas and the carrier gas in the reaction container for silicidation is controlled to be 2.5 Torr. In this state, the polysilicon constituting the second gate pattern 213 is heated to a temperature of 300° C. at which the material gas thermally decomposes.

Then, the first metal and polysilicon are reacted with each other and thus the second gate pattern 213 is turned into the second gate electrode 218 constituted by Ni₃Si (silicide (B)) (second silicidation process; FIG. 15A). At this time, the deposition of the Ni film onto the second gate pattern 213 is not confirmed. After that, the unreacted metal layer 219 that has deposited on parts other than the first mask 217 and the second gate electrode 218 is removed (FIG. 15(b)).

As a result of the evaluation of the CV characteristic of the semiconductor device manufactured in this manner, it has been confirmed that the reversed capacitance and the cumulative capacitance are equal and by the application of the metal gate electrode, the depletion layer of the gate electrode can be suppressed. It has also been confirmed that the effective work function of the manufactured semiconductor device is 4.4 eV for the N-type MOSFET and 4.8 eV for the P-type MOSFET, and the modulation of the effective work function at 0.4 eV is available.

Further, as the result of the evaluation of the leak characteristic of the manufactured semiconductor device, the deterioration of the junction leak in the source/drain region is not found in any MOSFET. This indicates that the resistance or the composition/crystal phase of the silicide layer formed on the source/drain region has not changed at 300° C. to which the temperature is heated at the time of the silicidation to form the gate electrode by the manufacturing method of the present invention.

### Second Embodiment

A semiconductor device is manufactured in the same manner as that in the first embodiment except in that the formation conditions in the first and second silicidation processes are set as follows.

—First Silicidation Process—

Heating temperature of first gate pattern: 450° C.

Pressure in vacuum container: 2.5 Torr

Amount of supply of material gas: 80 sccm

Reaction time: 45 min

—Second Silicidation Process—

Heating temperature of second gate pattern: 300° C.

Pressure in vacuum container: 2.5 Torr

Amount of supply of material gas: 80 sccm

Reaction time: 20 min

The heating temperature of the first and second gate patterns described above is the temperature at which the material gas Ni(PF₃)₄ thermally decomposes. The deposition of the Ni film onto the first and second gate patterns is not confirmed at the time of the first and second silicidation processes.

In this manner, the complementary MOSFET including the composition/crystal phase of NiSi₂ (silicide (A)) as the first gate electrode for the N-type MOSFET and the composition/crystal phase of Ni₃Si (silicide (B)) as the second gate electrode for the P-type MOSFET can be obtained.

As a result of the evaluation of the CV characteristic of the semiconductor device manufactured in this manner, it has been confirmed that the reversed capacitance and the cumulative capacitance are equal and by the application of the metal gate electrode, the depletion layer of the gate electrode can be suppressed. It has also been confirmed that the effective work function of the manufactured semiconductor device is 4.4 eV for the N-type MOSFET and 4.8 eV for the P-type MOSFET, and the modulation of the effective work function at 0.4 eV is available.

Further, as the result of the evaluation of the leak characteristic of the manufactured semiconductor device, the deterioration of the junction leak in the source/drain region is not found in any MOSFET. This indicates that the resistance or the composition/crystal phase of the silicide layer formed on the source/drain region has not changed at 300° C. and 450° C. to which the temperature is heated at the time of the silicidation to form the gate electrode by the manufacturing method of the present invention.

### Third Embodiment

A semiconductor device is manufactured in the same manner as that in the first embodiment except in that the formation conditions in the first and second silicidation processes are set as follows.

—First Silicidation Process—

Heating temperature of first gate pattern: 360° C.

Pressure in vacuum container: 2.5 Torr

Amount of supply of material gas: 20 sccm

Reaction time: 45 min

—Second Silicidation Process—

Heating temperature of second gate pattern: 360° C.

Pressure in vacuum container: 0.01 Torr

Amount of supply of material gas: 20 sccm

Reaction time: 20 min

The heating temperature of the first and second gate patterns described above is the temperature at which the material gas Ni(PF₃)₄ thermally decomposes. The deposition of the Ni film onto the first and second gate patterns is not confirmed at the time of the first and second silicidation processes.

In this manner, the complementary MOSFET including the composition/crystal phase of NiSi₂(silicide (A)) as the first gate electrode for the N-type MOSFET and the composition/crystal phase of Ni₃Si (silicide (B)) as the second gate electrode for the P-type MOSFET can be obtained.

As a result of the evaluation of the CV characteristic of the semiconductor device manufactured in this manner, it has been confirmed that the reversed capacitance and the cumulative capacitance are equal and by the application of the metal gate electrode, the depletion layer of the gate electrode can be suppressed. It has also been confirmed that the effective work function of the manufactured semiconductor device is 4.4 eV for the N-type MOSFET and 4.8 eV for the P-type MOSFET, and the modulation of the effective work function at 0.4 eV is available.

Further, as the result of the evaluation of the leak characteristic of the manufactured semiconductor device, the deterioration of the junction leak in the source/drain region is not found in any MOSFET. This indicates that the resistance or the composition/crystal phase of the silicide layer formed on the source/drain region has not changed at 360° C. to which the temperature is heated at the time of the silicidation to form the gate electrode by the manufacturing method of the present invention.

### Fourth Embodiment

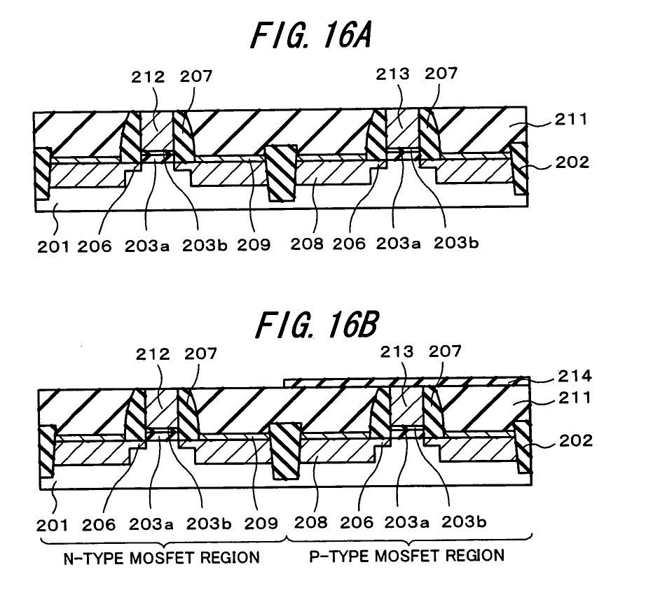

FIGS. 16 to 18 are cross-sectional views showing manufacturing processes of a semiconductor device in the present embodiment. First, as in the first embodiment in FIGS. 11 to 13, the gate insulating films 203a and 203b, the first gate pattern 212, the second gate pattern 213, and the gate sidewall 207 are formed on a silicon substrate and the extension diffusion layer region 206 and the source/drain region 208 are formed in the silicon substrate, and then, the first and second gate patterns 212, 213 are exposed. FIG. 16A shows a state where the first gate pattern 212 and the second gate pattern 213 are exposed. As the first and second gate patterns 212, 213, a non-doped polysilicon having a film thickness of 60 nm is formed.

Next, TiN having a film thickness of 20 nm is deposited on the entire surface as the diffusion preventive layer 214 by the reactive sputtering method. After that, the first gate pattern 212 is exposed by removing the diffusion preventive layer 214 provided on the first gate pattern 212 using the lithography technique and the RIE technique. FIG. 16(b) shows a state where the second mask 214 is provided on the second gate pattern 213 by thus removing the diffusion preventive layer 214 on the first gate pattern 212.

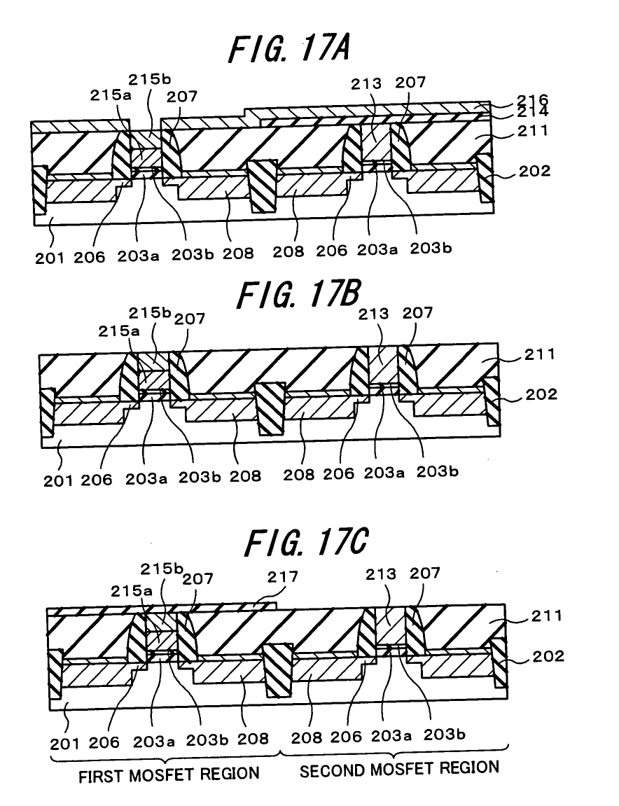

Next, the structure in FIG. 16(b) is introduced into the manufacturing apparatus shown in FIG. 1 in order to form the first gate electrode by silicidating the first gate pattern 212 (first silicidation process). Here, the first silicidation is carried out in two stages. That is, as the first formation conditions, the first gate pattern 212 is heated to 300° C. as the temperature at which the material gas thermally decomposes, the pressure in the vacuum container is set to 2.5 Ton, the amount of supply of Ni(PF₃)₄ (material gas) is set to 2 sccm, and as the carrier gas, N₂ is introduced at 100 sccm (supply amount) for 45 minutes, and thus a first silicide layer 215a is formed. After that, as the second formation conditions, only the amount of supply of the material gas is changed to 50 sccm and introduced for 200 seconds, and thus a second silicide layer 215b is formed (FIG. 17A; first silicidation process).

After that, the unreacted metal layer 216 that has deposited on parts other than the second mask 214 and the first gate electrode is removed by wet etching using the sulfuric acid hydrogen peroxide solution (FIG. 17(b)). Next, after a TiN film having a film thickness of 20 nm is deposited on the entire surface as the diffusion preventive layer 217 by the reactive sputtering method, the TiN film that has deposited on the second gate pattern 213 is removed using the lithography technique and the RIE (Reactive Ion Etching) technique. Thereby, the first mask 217 is formed on the first gate electrode (FIG. 17C).

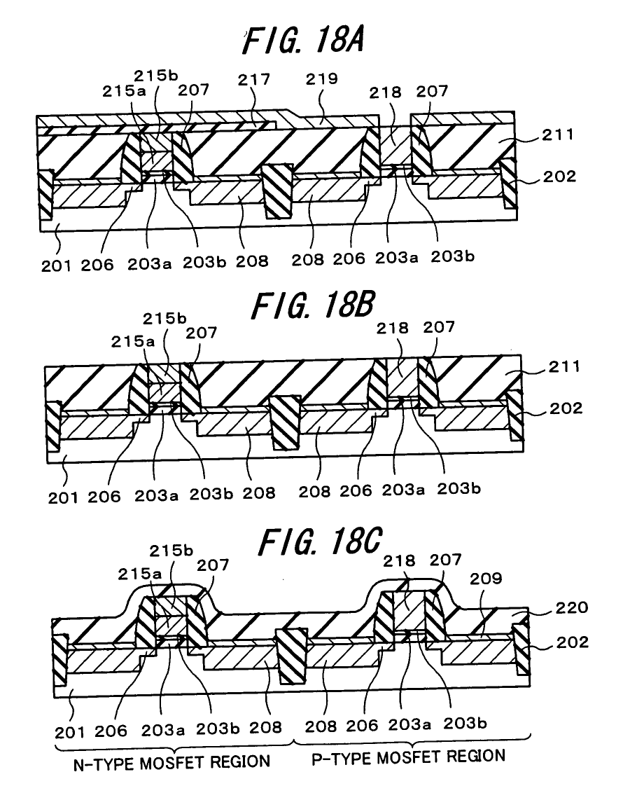

After that, the structure shown in FIG. 17C is introduced into the manufacturing apparatus and the second gate pattern 213 is heated to 300° C. as the temperature at which the material gas thermally decomposes, the pressure in the vacuum container is set to 2.5 Torr, the amount of supply of Ni(PF₃)₄ (material gas) is set to 80 sccm, and as the carrier gas, N₂ is introduced at 100 sccm for 20 minutes, and thus the second gate electrode of the silicide layer 218 is formed (second silicidation process; FIG. 18A).

The deposition of the Ni film onto the first and second gate patterns is not confirmed at the time of the first and second silicidation processes.

After that, the unreacted metal layer 219 that has deposited on parts other than the first mask 217 and the second gate electrode 218 is removed by wet etching using the sulfuric acid hydrogen peroxide solution (FIG. 18(b)). Then, after the interlayer insulating film 211 is removed by wet etching using the HF aqueous solution, the silicon nitride film 220 is formed so as to cover the entire semiconductor device.

As a result, the gate electrode can be obtained, which has a laminated structure in which the first gate electrode has the NiSi₂ crystal phase 215a (silicide (A)) as the first silicide layer and the NiSi crystal phase 215b (silicide (A)) as the second silicide layer on the first silicide layer. In addition, the second electrode 218 (silicide (B)) having the Ni₃Si crystal phase can be formed. Then, the complementary MOSFET (CMOSFET) comprising the first and second gate electrodes as described above can be manufactured. It has been confirmed that the first gate electrode is not etched by the HF aqueous solution from the result of the cross section observation by SEM.

As described above, it has been proven that the manufacturing method of a semiconductor device of the present invention has an advantage of capable of successively forming a laminated structure having a resistant property against etching by the HF aqueous solution and having the NiSi crystal phase on the NiSi₂ crystal phase.

### Fifth Embodiment

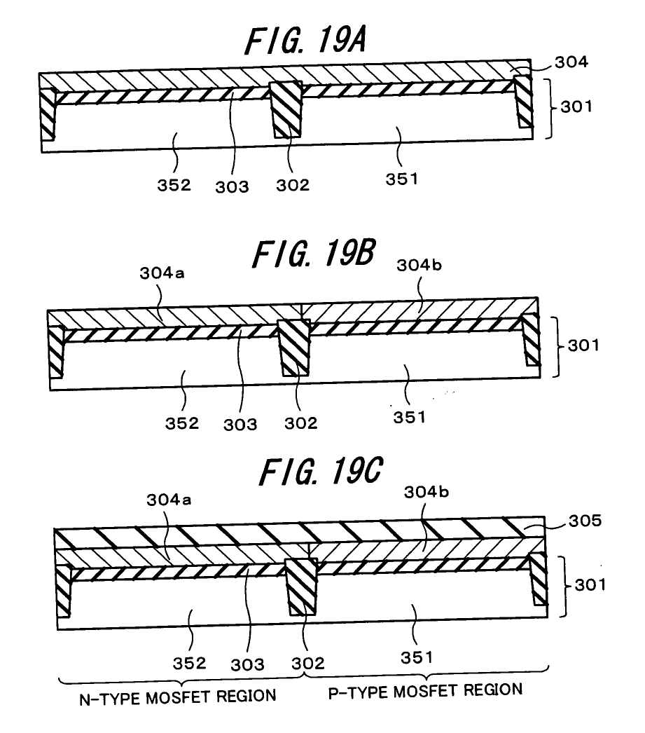

FIG. 19 to FIG. 22 are cross-sectional views showing the manufacturing method of MOSFET in the present embodiment. First, a silicon substrate 301 having an N-type region (N-type active region; N well) 351 and a P-type region (P-type active region; P well) 352 is prepared. Next, an element isolation region 302 is formed in the silicon substrate 301 so that the N-type region 351 and the P-type region 352 are insulated and isolated using the STI technique. Subsequently, a gate insulating film 303 is formed on the surface of the silicon that has been element-isolated. As the gate insulating film, a silicon oxynitride film having a film thickness of 3 nm is used.

Next, a poly-Si film 304 having a film thickness of 80 nm is formed on the gate insulating film formed as described above (FIG. 19A). Different kinds of ion impurity are implanted into a poly-Si region 304a in the N-type MOSFET region and a poly-Si region 304b in the P-type MOSFET region, respectively, by combining the normal PR process using a resist for the poly-Si and the ion implantation.

That is, a mask (not shown) is provided on the poly-Si 304 on the N-type region 351 and the poly-Si 304a containing impurity elements is obtained by implanting As into the poly-Si 304 on the P-type region 352 (FIG. 19(b)). Then, after the mask provided on the poly-Si 304 on the N-type region 351 is removed, a mask (not shown) is provided on the P-type region and the poly-Si 304b containing impurity elements is obtained by implanting B into the poly-Si 304 on the N-type region 351. Each implantation energy and amount of dose for the implantation of As are set to 5 KeV and 1×10¹⁵ cm⁻² to 5×10¹⁵ cm⁻², and for the implantation of B, to 2 KeV and 1×10⁻¹⁵ cm^{˜}2 to 6×10⁻¹⁵ cm⁻².

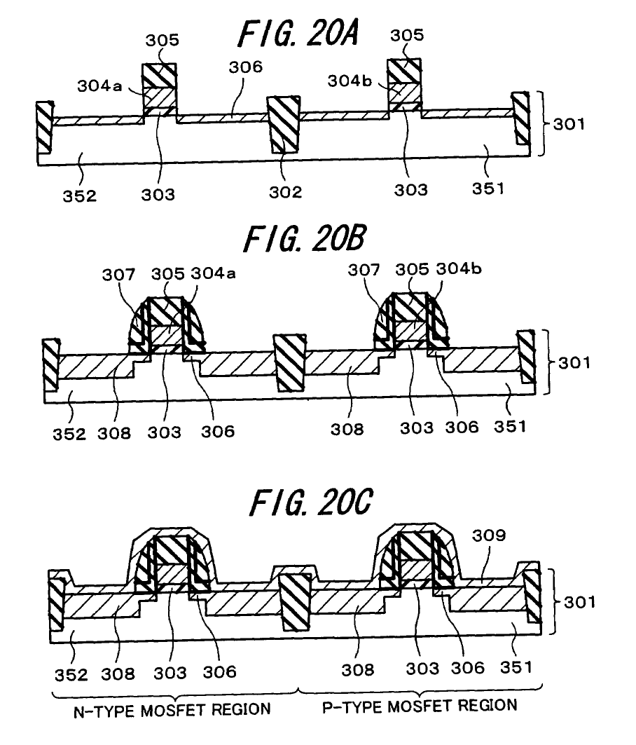

After that, as shown in FIG. 19C, a laminated film constituted by a silicon oxide film 305 having a film thickness of 150 nm is formed. The laminated film is processed to form the gate insulating film 303 in the form of a projection, the first gate pattern 304a, and the mask 305 on the P-type region 352, and the gate insulating film 303 in the form of a projection, the second gate pattern 304b, and the mask 305 on the N-type region 351 using the lithography technique and the RIE technique. Subsequently, ions are implanted into the N-type region 351 and the P-type region 352 and an extension diffusion region 306 is formed in a self-alignment manner in the N-type region 351 and the P-type region 352 (FIG. 20A).

Further, the silicon nitride film and the silicon oxide film are deposited sequentially and then, a gate sidewall 307 is formed on both side surfaces of the gate insulating film 303 in the form of a projection, the first gate pattern 304a, and the mask 305, and on both side surfaces of the gate insulating film 303 in the form of a projection, the second gate pattern 304b, and the mask 305, respectively, by carrying out etch-back. In this state, ions are implanted again into the N-type region 351 and the P-type region 352, respectively, and thus a source/drain diffusion layer 308 is formed through the activation annealing (FIG. 20(b)).

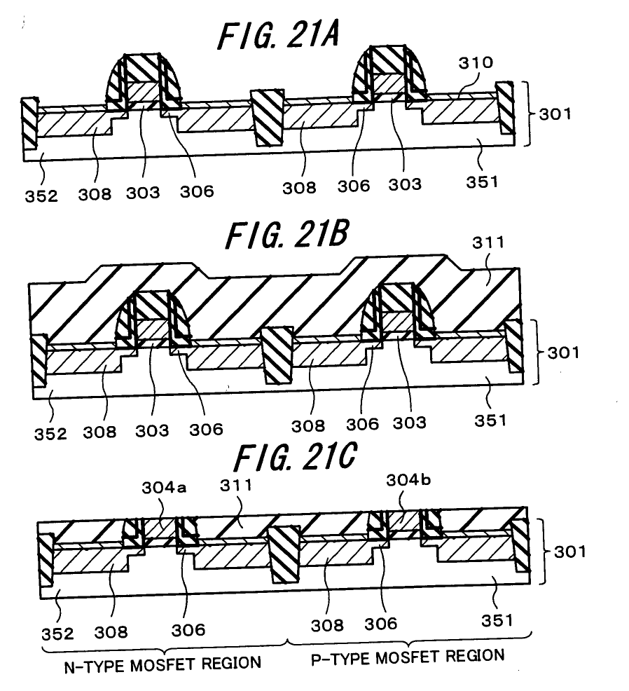

Next, a metal film 309 having a film thickness of 20 nm is deposited on the entire surface by the sputtering method and a silicide layer 310 having a film thickness of about 40 nm is formed only on the source/drain diffusion layer 308 using the gate electrode, the gate sidewall film, and STI as a mask by the salicide technique (FIG. 20C). The silicide layer is formed so as to be one having the NiSi crystal phase that can minimize the contact resistance (FIG. 21A).

Further, as shown in FIG. 21(b), an interlayer insulting film 311 constituted by a silicon oxide film is formed by the CVD method. The interlayer insulating film 311 is flattened by the CMP technique as shown in FIG. 21C, and by further carrying out etch-back, the first gate pattern 304a and the second gate pattern 304b are exposed.

After that, the structure is introduced into the manufacturing apparatus shown in FIG. 1 and the first and second gate patterns 304a, 304b are heated simultaneously to 300° C. as the temperature at which the material gas thermally decomposes, the pressure in the vacuum container is set to 2.5 Torr, the amount of supply of Ni(PF₃)₄ (material gas) is set to 2 sccm, and as the carrier gas, N₂ is introduced at 100 sccm for 45 minutes, and thus a silicide layer having the composition/crystal phase of NiSi₂ (silicides (A), (B)) is formed (first and second silicidation processes). At the time of the first and second silicidation processes, the deposition of the Ni film onto the first and second gate patterns is not confirmed. After that, the excessive Ni film that has not reacted for silicidation is removed by wet etching using the sulfuric acid hydrogen peroxide solution.

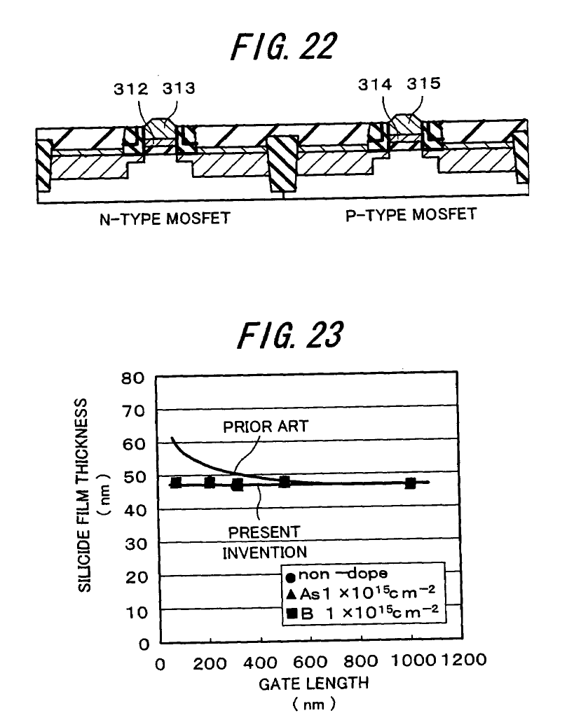

Through the above-described processes, the complementary MOSFET as shown in FIG. 22 is formed, in which the first gate electrode and the second gate electrode have the same silicide composition, however, different additive elements are segregated at the boundary surface between the gate electrode and the gate insulating film. The effective work function of the semiconductor device thus manufactured is 4.0 eV for the N-type MOSFET and 5.2 eV for the P-type MOSFET.

According to the evaluation of the leak characteristic of the semiconductor device, the deterioration of the junction leak in the source/drain region is not found in any MOSFET. This indicates that the resistance or the composition/crystal phase of the silicide layer formed on the source/drain region has not changed at 300° C. to which the temperature is heated at the time of the silicidation to form the gate electrode by the manufacturing method of the present invention.

As described above, it has been proven that the process of annealing processing that has been necessary conventionally can be reduced and the silicide layer having the NiSi₂ crystal phase can be formed at a low temperature at which the resistance and the crystal phase of the NiSi layer on the source/drain region are not affected, which has been difficult conventionally, by using the manufacturing method of a semiconductor device according to the present invention.

FIG. 23 shows the relationship between the film thickness of the silicide layer constituting the gate electrode, the doping ion kinds of polysilicon, and the gate length in the present embodiment. The result of a case, as a comparative example, where the Ni metal film is formed by the sputtering method and the annealing processing is carried out, and thus the silicide layer constituting the gate electrode is formed is shown in FIG. 23. From FIG. 23, it can be confirmed that as the gate length becomes shorter, the film thickness of the silicide layer increases according to the prior art. This is because not only that the polysilicon reacts with the Ni metal film on the polysilicon but also that Ni is also supplied from the Ni metal film on the interlayer insulating film and the silicide layer is formed by its reaction as shown in FIG. 4.

In contrast to this, in the manufacturing method of a semiconductor device according to the present invention, it can be confirmed that the film thickness of the silicide layer is substantially the same irrespective of the gate length and the doping ion kind. The reason for this can be thought that in the manufacturing method of a semiconductor device according to the present invention, the silicide layer is formed only by the thermal decomposition of the material gas without depositing the Ni metal film on the polysilicon (without carrying out the annealing process).

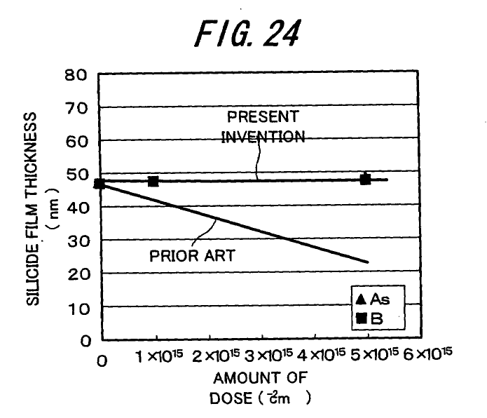

FIG. 24 shows the relationship between the film thickness of the silicide layer constituting the gate electrode in the present embodiment and the amount of dose of the doping ion in the gate electrode. Further, a case where the Ni metal film is formed by the sputtering method and then the annealing processing is carried out and thus the silicide layer is formed is shown in FIG. 24 as a comparative example. From FIG. 24, it can be confirmed that as the amount of dose of the doping ion increases, the film thickness of the silicide layer reduces in the prior art.

In contrast to this, it can be confirmed that the film thickness of the silicide layer is substantially the same irrespective of the amount of dose of the doping ion in the manufacturing method of a semiconductor device according to the present invention. The reason for this can be thought that the silicide layer is formed only by the thermal decomposition reaction of the material gas without depositing the Ni metal film on the polysilicon and the silicide layer is formed in the state where the supply rate is limited by the control of the material gas in the manufacturing method of a semiconductor device according to the present invention while the silicide layer is formed by the solid phase reaction in the prior art.

From these results, with the manufacturing method of a semiconductor device according to the present invention, it is possible to make the formation rate and the composition/crystal phase fixed irrespective of the kind of impurity in the gate electrode, the amount of impurity, and the size of the exposed region.

### Sixth Embodiment

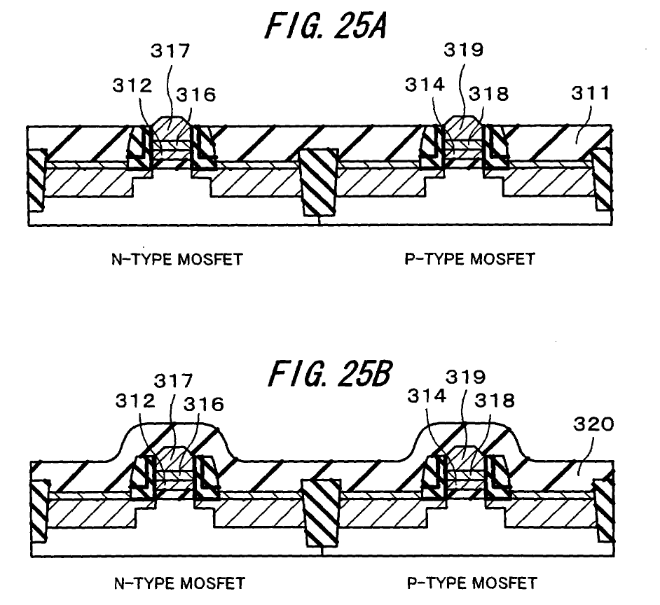

FIG. 25 is a cross-sectional view showing a manufacturing process of a semiconductor device according to the present embodiment. First, as in the fifth embodiment, the upper surface of the poly-Si film 304 for the gate electrode is exposed (the same structure as that in FIG. 21C). Next, the first and second gate patterns 304a, 304b are introduced into the manufacturing apparatus shown in FIG. 1 and the first and second silicidation processes are carried out simultaneously in two stages. Here, as the first conditions, the gate pattern is heated to 300° C. as the temperature at which the material gas thermally decomposes, the formation pressure is set to 2.5 Torr, the amount of supply of Ni(PF₃)₄ (material gas) is set to 2 sccm, as the carrier gas, N₂ is introduced at 100 sccm for 45 minutes, and thus first silicide layers 316 and 318 are formed on the P-type region and the N-type region, respectively. After that, as the second formation conditions, only the amount of supply of the material gas is changed to 50 sccm and the material gas is introduced into the reaction container for 200 seconds and thus second silicide layers 317 and 319 are formed on the first silicide layers 316 and 318, respectively (FIG. 25A). At the time of the first and second silicidation processes, the deposition of the Ni film onto the first and second gate patterns is not confirmed.

After that, the excessive Ni film that has not been subjected to the silicidation reaction is removed by wet etching using the sulfuric acid hydrogen peroxide solution. Then, the interlayer insulating film 311 is removed by wet etching using the HF aqueous solution and a silicon nitride film 320 is formed so as to cover the gate pattern (FIG. 25(b)).

As a result, a silicide layer can be obtained, which has a laminated structure in which the first and second gate electrodes include the NiSi₂ crystal phase as the first silicide layer and the NiSi crystal phase as the second silicide layer on the first silicide layer. In addition, it has been confirmed that the first and second gate electrodes are not etched by the HF aqueous solution from the result of cross section observation by SEM.

As described above, it has been proven that the manufacturing method of a semiconductor device of the present invention is capable of successively forming a laminated structure of the NiSi₂ crystal phase and the NiSi crystal phase having a resistant property against etching by the HF aqueous solution.

### Seventh Embodiment

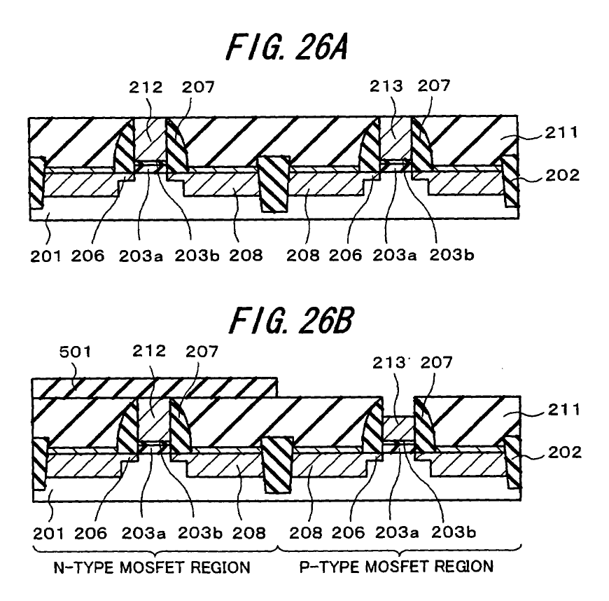

FIG. 26 to FIG. 28 are cross-sectional views showing manufacturing processes of a semiconductor device in the present embodiment. First, as in FIG. 11 to FIG. 13A in the first embodiment, a structure in FIG. 26A is formed. Here, as the first and second gate patterns 212 and 213, a non-doped polysilicon having a film thickness of 60 nm is formed.

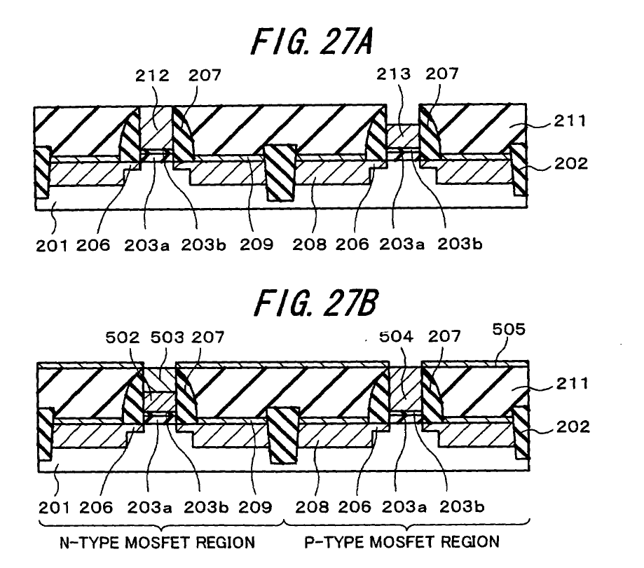

Next, a silicon oxide film 501 having a film thickness of 150 nm is deposited on the entire surface by the CVD method. After that, the silicon oxide film 501 provided on the second gate pattern 213 is removed using the lithography technique and the RIE technique, and then, the second gate pattern 213 is etched so as to have a film thickness of 30 nm (FIG. 26(b)). Next, the silicon oxide film 501 on the first gate pattern 212 is removed and thus the first gate pattern and the second gate patterns are exposed (FIG. 27A).

Next, the structure is introduced into the manufacturing apparatus shown in FIG. 1 and the first and second silicidation processes in two stages are carried out simultaneously. Here, as the first conditions, the first and second gate patterns 212 and 213 are heated to 300° C. as the temperature at which the material gas thermally decomposes, the formation pressure is set to 2.5 Torr, the amount of supply of Ni(PF₃)₄ (material gas) is set to 2 sccm, as the carrier gas, N₂ is introduced at 100 sccm (amount of supply) for 45 minutes, and thus first silicide layers 502 and 504 are formed. After that, as the second formation conditions, only the amount of supply of the material gas is changed to 80 sccm and the material gas is introduced for 200 seconds, and thus a second silicide layer 503 is formed on the first silicide layer 502 and at the same time, the silicide layer 504 is formed standalone on the N-type region.

Here, while a laminated structure of the first silicide layer and the second silicide layer is formed for the first gate pattern 212 due to the above-described silicidation conditions, it is made possible to form a silicide layer having all of the single silicide compositions when forming the first and second silicide layers because the film of the second gate pattern 213 is thin. Further, it is possible for the silicide layer constituting the second gate electrode to have a Ni content higher than that of the silicide layer constituting the first gate electrode. The deposition of the Ni film onto the first and second gate patterns is not confirmed at the time of the first and second silicidation processes.

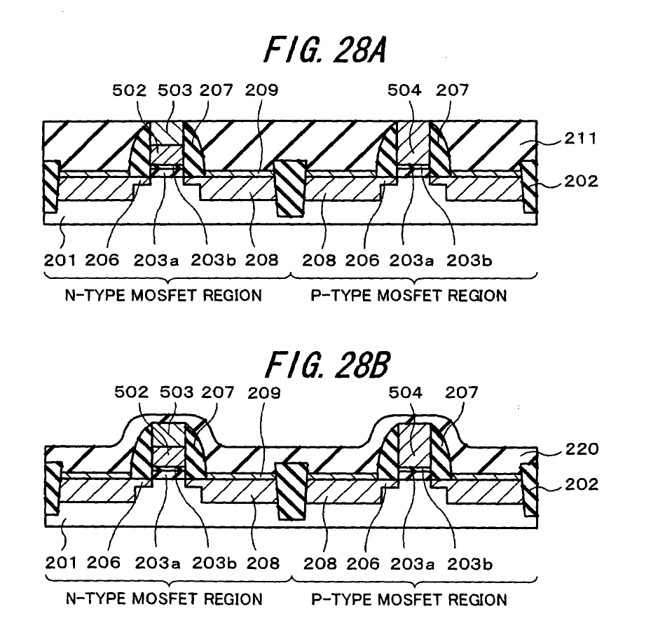

After that, an unreacted metal layer 505 that has deposited on parts other than the first and second gate electrodes is removed by wet etching using the sulfuric acid hydrogen peroxide solution (FIG. 28A). Then, after the interlayer insulating film 211 is removed by wet etching using the HF aqueous solution, the silicon nitride film 220 is formed so as to cover the entire semiconductor device (FIG. 28(b)).

As a result, the gate electrode can be obtained, which has a laminated structure in which the first gate electrode has the NiSi₂ crystal phase (silicide (A)) as the first silicide layer and the NiSi₃ crystal phase (silicide (A)) as the second silicide layer on the first silicide layer. In addition, the second electrode having the Ni₃Si crystal phase (silicide (B)) can be formed. This has taken place in such a manner that the second gate pattern turns into the NiSi crystal phase at the time of the formation of the first silicide layer of the first gate electrode and further, the NiSi crystal phase turns into the Ni₃Si crystal phase (silicide (B)) at the time of the formation of the second silicide layer of the first gate electrode. Then, the complementary MOSFET (CMOSFET) comprising the first and second gate electrodes as described above can be manufactured. It has been confirmed that the first gate electrode is not etched by the HF aqueous solution from the result of cross section observation by SEM.

As described above, it has been proven that the manufacturing method of a semiconductor device of the present invention is capable of successively forming a laminated structure of the Ni₃Si crystal phase and the NiSi crystal phase having a resistant property against etching by the HF aqueous solution as the gate electrode. Further, it is possible to form at one time the silicide layers of different compositions in the N-type MOSFET and the P-type MOSFET without the need to drastically increase the number of additional processes by changing the film thickness of the poly-Si constituting the first gate pattern and the second gate pattern.

### Reference Sample 1

In the present embodiment, the semiconductor device is manufactured using Ni (BF₂)₄, Pt(PF₃)₄, Pt(BF₂)₄, Co(PF₃)₆, Co(BF₂)₆, W(PF₃)₆, W(BF₂)₆, Ru(PF₃)₅, and Ru (BF₂)₅, as the material gas. Further, according to the kind of material gas, the amount of supply of the material gas is set to a range of 2 to 100 sccm, the heating temperature of the first and second gate patterns to a range of 150° C. to 600° C., and the formation pressure to a range of 1×10⁻⁴ Torr to 100 Torr.

In this reference example, the same evaluation as that in the first embodiment is made, and as a result, it is confirmed that the gate electrode of the silicide layer can be formed under the conditions that the metal layers of Ni, Pt, Co, W, Ru are not allowed to deposit on the exposed polysilicon, respectively. It is also confirmed that the gate electrode of the silicide layer with a laminated structure can be formed, in which the metal containment of the silicide layer increases at the upper part by optimizing the formation profile of the silicide layer. In addition, a complementary MOSFET in which the composition ratio of the first gate electrode is different from that of the second gate electrode can be obtained.

### Reference Example 2

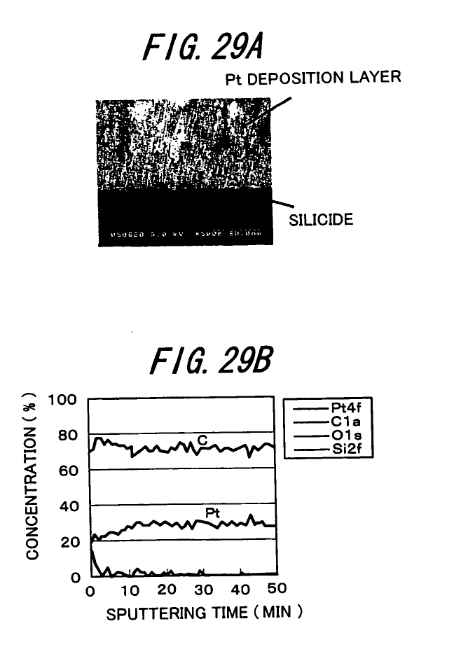

In the present embodiment, the same conditions as those in the first embodiment are set except in that the gate electrode of the silicide layer is formed using CpAllylPt (cyclopentadienylallyl-platinum) containing C in the material gas. FIG. 29A and FIG. 29(b) show the result of cross section observation by SEM of the silicide layer formed in the present embodiment and the composition analysis result by XPS. From FIG. 29, it can be seen that the formation of the silicide layer advances only locally and the metal Pt layer is formed on the substrate. It can also be seen that C is contained much in the metal Pt layer from the composition analysis by XPS. From these, it can be seen that C constituting the material gas attaches to the substrate surface and impedes silicidation. Consequently, it can be seen that preferably C is not contained as the constituent element of the material gas.

This application is based on and claims the priority of Japanese Patent Application No. 2006-268017, filed Sep. 29, 2006, and the disclosure of which is incorporated herein in its entirety.

### INDUSTRIAL APPLICABILITY

The present invention is a technique relating to a semiconductor device and its manufacturing method and, more particularly, to a semiconductor device in which its silicide layer constituting a gate electrode is formed in a special process, and its manufacturing method.

1. A manufacturing method of a semiconductor device comprising N-type MOSFET and P-type MOSFET of planar type, including:
a process for preparing a silicon substrate on which an N-type region and a P-type region are insulated and isolated via an element isolation region;
a first formation process for forming a gate insulating film and a first gate pattern constituted by polysilicon in the form of a projection on the P-type region, and forming a gate insulating film and a second gate pattern constituted by polysilicon in the form of a projection on the N-type region;
a second formation process for forming source/drain regions on both sides of the first gate pattern in the P-type region and on both sides of the second gate pattern in the N-type region, respectively;
a process for depositing an interlayer insulating film on the entire surface;
a process for removing the interlayer insulating film to expose the first and second gate patterns;
a process for providing a second mask so as to cover the region on the gate insulating film provided on the N-type region;
a first silicidation process for supplying a material gas containing a first metal that can be used to form a silicide with polysilicon constituting the first gate pattern, heating the first gate pattern to a temperature at which the material gas thermally decomposes, causing the first metal and the polysilicon constituting the first gate pattern to react with each other under the conditions that the layer of the first metal does not deposit on the first gate pattern, and thus turning the first gate pattern into a first gate electrode constituted by a silicide (A) of the first metal;
a process for removing the layer of the first metal that has deposited on parts other than the second mask and the first gate electrode;
a process for providing a first mask so as to cover the region on the gate insulating film provided on the P-type region;
a second silicidation process for supplying a material gas containing the first metal that can be used to form a silicide with polysilicon constituting the second gate pattern, heating the second gate pattern to a temperature at which the material gas thermally decomposes, causing the first metal and the polysilicon constituting the second gate pattern to react with each other under the conditions that the layer of the first metal does not deposit on the second gate pattern, and thus turning the second gate pattern into a second gate electrode constituted by a silicide (B) of the first metal; and
a process for removing the layer of the first metal that has deposited on parts other than the first mask and the second gate electrode.

2. The manufacturing method of a semiconductor device according to claim 1,
wherein
in the first formation process, as the gate insulating film, a silicon oxide film or a silicon oxynitride film is formed, as the first gate pattern, polysilicon containing at least one kind of impurity element selected from a group consisting of N, P, As, Sb, and Bi is formed, and as the second gate pattern, polysilicon containing at least one kind of impurity element selected from a group consisting of B, Al, Ga, In, and Tl is formed.

3. The manufacturing method of a semiconductor device according to claim 1, wherein
the first and second silicidation processes are carried out so that the silicide (A) and the silicide (B) are silicides having different composition ratios of the first metal and the silicon from each other.

4. The manufacturing method of a semiconductor device according to claim 1, wherein
at least one process of the first and second silicidation processes has a first silicide layer formation process for forming a first silicide layer and a second silicide layer formation process for forming a second silicide layer with a first metal content higher than that of the first silicide layer on the first silicide layer by supplying a material gas under the conditions that the amount of supply of the material gas is larger than that in the first silicide layer formation process.

5. The manufacturing method of a semiconductor device according to claim 1, wherein
at least one process of first and second silicidation processes has a first silicide layer formation process for forming a first silicide layer and a second silicide layer formation process for forming a second silicide layer with a first metal content higher than that of the first silicide layer on the first silicide layer by reducing the temperature at which the material gas thermally decomposes lower than that in the first silicide layer formation process.

6. The manufacturing method of a semiconductor device according to claim 1, wherein
at least one process of first and second silicidation processes has a first silicide layer formation process for forming a first silicide layer and a second silicide layer formation process for forming a second silicide layer with a first metal content higher than that of the first silicide layer on the first silicide layer by reducing the atmospheric pressure when the first metal is reacted with polysilicon lower than that in the first silicide layer formation process.

7. The manufacturing method of a semiconductor device according to claim 3, wherein
the amount of supply of the material gas in the second silicidation process is larger than the amount of supply of the material gas in the first silicidation process.

8. The manufacturing method of a semiconductor device according to claim 3, wherein
the heating temperature of polysilicon constituting the second gate pattern in the second silicidation process is lower than the heating temperature of polysilicon constituting the first gate pattern in the first silicidation process.

9. The manufacturing method of a semiconductor device according to claim 3, wherein
the atmospheric pressure when the first metal is reacted with the polysilicon in the second silicidation process is lower than the atmospheric pressure when the first metal is reacted with the polysilicon in the first silicidation process.

10. The manufacturing method of a semiconductor device according to claim 1, wherein
the first metal is at least one kind of metal selected from a group consisting of Ni, Pt, Co, W, and Ru.

11. The manufacturing method of a semiconductor device according to claim 1, wherein
the material gas does not contain C in the first and second silicidation processes.

12. The manufacturing method of a semiconductor device according to claim 1, wherein
the material gas contains at least one kind of gas selected from a group consisting of Ni(PF₃)₄, Ni(BF₂)₄, Pt(PF₃)₄, Pt(BF₂)₄, Co(PF₃)₆, Co(BF₂)₆, W(PF₃)₆, W(BF₂)₆, Ru(PF₃)₅, and Ru(BF₂)₅.

13. The manufacturing method of a semiconductor device according to claim 1, wherein
in at least one process of the first and second silicidation processes, the material gas is Ni(PF₃)₄ or Ni(BF₂)₄, and as at least one silicide of the silicide (A) and the silicide (B), a NiSi₂ crystal phase is formed.

14. The manufacturing method of a semiconductor device according to claim 13, wherein
in at least one process of the first and second silicidation processes, as the conditions that the layer of the first metal does not deposit on the gate pattern, at least one gate pattern of the first and second gate patterns is heated to 150° C. to 600° C. as the temperature at which the material gas thermally decomposes.

15. The manufacturing method of a semiconductor device according to claim 13, wherein
in at least one process of the first and second silicidation processes, as the conditions that the layer of the first metal does not deposit on the gate pattern, the atmospheric pressure when polysilicon constituting at least one gate pattern of the first and second gate patterns is reacted with the first metal is set to 1×10⁻⁴ Torr to 100 Torr.

16. The manufacturing method of a semiconductor device according to claim 1, wherein
in at least one process of the first and second silicidation processes, the material gas is Ni(PF₃)₄ or Ni(BF₂)₄ and as at least one silicide of the silicide (A) and the silicide (B), a NiSi crystal phase is formed.

17. The manufacturing method of a semiconductor device according to claim 16, wherein
in at least one process of the first and second silicidation processes, as the conditions that the layer of the first metal does not deposit on the gate pattern, at least one gate pattern of the first and second gate patterns is heated to 250° C. to 600° C. as the temperature at which the material gas thermally decomposes.

18. The manufacturing method of a semiconductor device according to claim 16, wherein
in at least one process of the first and second silicidation processes, as the conditions that the layer of the first metal does not deposit on the gate pattern, the atmospheric pressure when polysilicon constituting at least one gate pattern of the first and second gate patterns is reacted with the first metal is set to 1×10⁻⁴ Torr to 80 Torr.

19. The manufacturing method of a semiconductor device according to claim 1, wherein
in at least one process of the first and second silicidation processes, the material gas is Ni(PF₃)₄ or Ni(BF₂)₄ and as at least one silicide of the silicide (A) and the silicide (B), a Ni₃Si crystal phase is formed.

20. The manufacturing method of a semiconductor device according to claim 19, wherein
in at least one process of the first and second silicidation processes, as the conditions that the layer of the first metal does not deposit on the gate pattern, at least one gate pattern of the first and second gate patterns is heated to 250° C. to 500° C. as the temperature at which the material gas thermally decomposes.

21. The manufacturing method of a semiconductor device according to claim 19, wherein
in at least one process of the first and second silicidation processes, as the conditions that the layer of the first metal does not deposit on the gate pattern, the atmospheric pressure when polysilicon constituting at least one gate pattern of the first and second gate patterns is reacted with the first metal is set to 1×10⁻⁴ Torr to 10 Torr.

22. The manufacturing method of a semiconductor device according to claim 1, wherein
in at least one process of the first and second silicidation processes, the material gas is Ni(PF₃)₄ or Ni(BF₂)₄ and the process has a first silicide layer formation process for forming a first silicide layer including the NiSi₂ crystal phase, and a second silicide layer formation process for forming a second silicide layer including at least one crystal phase of the NiSi crystal phase and the Ni₃Si crystal phase on the first silicide layer.

23. The manufacturing method of a semiconductor device according to claim 1, wherein
in the first silicidation process, the material gas is Ni(PF₃)₄ or Ni(BF₂)₄ and the NiSi₂ crystal phase is formed as the silicide (A), and in the second silicidation process, the material gas is Ni(PF₃)₄ or Ni(BF₂)₄ and the Ni₃Si crystal phase is formed as the silicide (B).

24. The manufacturing method of a semiconductor device according to claim 1, wherein
in the first silicidation process, the material gas is Ni(PF₃)₄ or Ni(BF₂)₄ and the process has the first silicide layer formation process for forming the first silicide layer constituted by the NiSi₂ crystal phase as the silicide (A), and the second silicide layer formation process for forming the second silicide layer constituted by the NiSi crystal phase as the silicide (A) on the first silicide layer, and in the second silicide formation process, the material gas is Ni(PF₃)₄ or Ni(BF₂)₄ and the Ni₃Si crystal phase is formed as the silicide (B).

25. A semiconductor device comprising:
an N-type MOSFET having a P-type region provided in a silicon substrate, a gate insulating film provided on the P-type region, and a first gate electrode in the form of a projection provided on the gate insulating film, having a first silicide layer constituted by a NiSi₂ crystal phase and a second silicide layer constituted by a Ni₃Si crystal phase in this order from the side of the gate insulating film; and
a P-type MOSFET having an N-type region provided in the silicon substrate so as to be insulated and isolated from the P-type region, a gate insulating film provided on the N-type region, and a second gate electrode constituted by a Ni₃Si crystal phase in the form of a projection provided on the gate insulating film.

26. A semiconductor device manufactured by the manufacturing method of a semiconductor device according to claim 1.
